(19) United States
(12) Patent Application Publication
(10) Pub. No.: US 2003/0224575 A1
(43) Pub. Date: Dec. 4, 2003

(54) Method of manufacturing a semiconductor integrated circuit device

(76) Inventors: Tatsuya Hinoue, Odawara (JP); Hideki Aono, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/445,403

(22) Filed: May 27, 2003

(30) Foreign Application Priority Data
May 28, 2002 (JP) 2002-154589

(51) Int. Cl. H01L 21/8234; H01L 29/76; H01L 29/94; H01L 31/062; H01L 31/113; H01L 31/119; H01L 21/20

(52) U.S. Cl. 438/275; 257/365; 438/391; 438/392

(57) ABSTRACT

Oxynitridation processing for heat treating a substrate in an atmosphere containing NO (nitrogen monoxide) and ion implantation of nitrogen are used in combination to control the concentration of nitrogen introduced near the boundary between a gate oxide film and a substrate (well), in the order of higher concentration given as: n-channel MISFET having a thick gate oxide film>n-channel MISFET having a thin gate oxide film>p-channel MISFET having the thick gate oxide film, p-channel MISFET having the thin gate oxide film, with no additional use of photomasks, whereby reliability to hot carriers and reliability to NBT can be compatibilized by optimizing the concentration of nitrogen introduced to the boundary between the gate oxide films of four types of MISFET of different conduction type and different gate oxide film thickness and the substrate (well).

### BACKGROUND OF THE INVENTION

The present invention concerns a semiconductor integrated circuit device and a manufacturing technique thereof and, more in particular, it relates to a technique of improving the device reliability such as hot carrier durability by optimizing the amount of nitrogen contained in the boundary between a gate insulative film and a semiconductor substrate of MISFET (Metal Insulator Semiconductor Field Effect Transistor).

It has been found in recent years that the hot carrier durability of n-channel type MISFET can be improved or leakage of boron (B) from p-type polycrystal silicon gates can be suppressed by introducing nitrogen atoms to the boundary between a gate insulative film and a silicon substrate by oxynitridation processing of a gate insulative film formed on a silicon substrate in a gas such as NO or N₂O, and this has been put to practical use, for example, in logic LSI.

Further, as a substitution method for the oxynitridation processing, it has been known that similar effects are obtainable by ion implanting nitrogen or nitrogen-containing ions during formation of source and drain extensions after fabrication of a gate electrode as described, for example, in Japanese Unexamined Patent Publication No. Hei 10(1998)-79506.

### SUMMARY OF THE INVENTION

In recent logic LSI, use of multiple power sources in one identical semiconductor type has been progressed, and a so-called 2-level gate insulative film structure of separately preparing a gate insulative film of a reduced thickness and a gate insulative film of a large thickness in one identical semiconductor chip has been put to practical use.

In a case of the logic LSI having the 2-level gate insulative film structure described above, it is known that deterioration of the reliability caused by hot carriers is more conspicuous in MISFET having a thick gate insulative film than in MISFET having a thin gate insulative film and that deterioration is more conspicuous in n-channel MISFET than in p-channel MISFET.

Further, it has been known that reliability to NBT is tended to be degraded more in the p-channel MISFET when the concentration of nitrogen at the boundary is excessively increased in a case of adopting the technique described above for introducing nitrogen atoms to the boundary between the gate oxide film and the silicon substrate for the improvement of the hot carrier durability of MISFET.

By the way, in a case of conducting the oxynitridation processing in a manufacturing step for LSI that constitutes circuits with complementary MISFET by adopting the 2-level gate insulative film structure, since nitrogen less permeates the thick gate insulation film compared with the thin gate insulative film, the nitrogen concentration is insufficient in the n-channel MISFET having the thick gate insulative film to result in a problem of deteriorating the hot carrier durability.

On the other hand, when the condition for the oxynitridation processing is determined in accordance with the n-channel MISFET having the thick gate insulative film, the nitrogen concentration in the p-channel MISFET becomes excessive to result in a problem of deteriorating the reliability to NBT.

The present invention intends to provide a technique capable of optimizing the reliability to hot carriers and reliability to NBT in a semiconductor integrated circuit in which a complementary MISFET having a thin gate insulative film and a complementary MISFET having a thick gate insulative film are present together.

The present invention further intends to provide a technique capable of optimizing the reliability to hot carriers and reliability to NBT in a semiconductor integrated circuit in which a complementary MISFET having a thin gate insulative film and a complementary MISFET having a thick gate insulative film are present together without increasing the number of photomasks.

The foregoing and other objects, as well as novel features of the present invention will become apparent by reading descriptions of the present specification and the appended drawings.

### SUMMARY OF THE INVENTION

Among the inventions described in the present application, outlines for typical inventions are briefly described below.

That is, a method of manufacturing a semiconductor integrated device according to the invention comprises the following steps of:

(a) forming a first insulative film to the surface of each of a first p-well, a second p-well, a first n-well and a second n-well formed to the main surface of a semiconductor substrate and then applying a heat treatment to the semiconductor substrate in an atmosphere containing nitrogen, thereby forming a first nitridation region having a first nitrogen concentration to the boundary between each of the wells and the first insulative film,

(b) removing the first insulative film and the first nitridation region formed in the first p-well, and the first insulative film and the first nitridation region formed in the first n-well, respectively, and leaving the first insulative film and the first nitridation region to the second p-well and the second n-well, respectively,

(c) applying thermal oxidation to the semiconductor substrate, thereby forming a first gate insulative film to the surface of each of the first p-well and the first n-well, and forming a second gate insulative film including the first insulative film as a portion thereof and having a thickness larger than that of the first gate insulative film to the surface of each of the second p-well and the second n-well,

(d) applying a heat treatment to the semiconductor substrate in an atmosphere containing nitrogen, thereby forming a second nitridation region having a second nitrogen concentration to the boundary between the first p-well and the first gate insulative film and to the boundary between the first n-well and the first gate insulative film, and forming a third nitridation region containing nitrogen in the first nitridation region as a portion thereof and having a third nitrogen concentration higher than the second nitrogen concentration to the boundary between the second p-well and the second gate insulative film and the boundary between the second n-well and the second gate insulative film,

(e) depositing a silicon film on the semiconductor substrate, then forming a first photoresist film on each of the first n-well and the second n-well, and forming an n-silicon film by ion implanting n-impurities to the silicon film above each of the first p-well and the second p-well,

(f) ion implanting nitrogen through the n-silicon film to each of the first p-well and the second p-well, while leaving the first photoresist film above each of the first n-well and the second n-well, thereby

forming a fourth nitridation region containing nitrogen in the second nitridation region as a portion thereof and having a fourth nitrogen concentration higher than the third nitrogen concentration to the boundary between the first p-well and the first gate insulative film, and

forming a fifth nitridation region containing nitrogen of the third nitridation region as a portion thereof and having a fifth nitrogen concentration higher than the fourth nitrogen concentration to the boundary between the second p-well and the second gate insulative film,

(g) forming a second photoresist film above each of the first p-well and the second p-well, and ion implanting p-impurities to the silicon film above each of the first n-well and the second n-well, thereby converting the same into a p-type silicon film,

(h) patterning each of the n-silicon film and the p-silicon film, thereby forming a n-semiconductor piece comprising the n-silicon film above each of the first p-well and the second p-well and forming a p-semiconductor piece comprising the p-silicon film above each of the first n-well and the second n-well,

(i) forming source and drain comprising an n-semiconductor region to each of the first p-well and the second p-well and forming source and drain comprising a p-semiconductor region to each of the first n-well and the second n-well after the step (h) described above, thereby

forming a first p-channel MISFET having source and drain comprising the p-semiconductor region, the first gate insulative film, a gate electrode including the p-semiconductor piece and the second nitridation region in the first n-well,

forming a second p-channel MISFET having source and drain comprising the p-semiconductor region, the second insulative film, a gate electrode including the p-semiconductor piece and the third nitridation region in the second n-well,

forming a first n-channel MISFET having source and drain comprising the n-semiconductor region, the first insulative film, a gate electrode including the n-semiconductor piece and the fourth nitridation region in the first p-well, and

forming a second n-channel MISFET having source and drain comprising the n-semiconductor region, the second insulative film, a gate electrode including the n-semiconductor piece and the fifth nitridation region in the second p-well.

According to the step (a) to the step (i) described above, the concentration of nitrogen introduced to the boundary between the second gate insulative film of the second n-channel MISFET and the semiconductor substrate is higher than the concentration of nitrogen introduced to the boundary between the first gate insulative film of the first n-channel MISFET (first gate insulative film) and the semiconductor substrate, and the concentration of nitrogen introduced to the boundary between the first gate insulative film of the first n-channel MISFET and the semiconductor substrate is higher than the concentration of the nitrogen introduced to the boundary between the first gate insulative film of the first p-channel MISFET and the semiconductor substrate, and the concentration of nitrogen introduced to the boundary between the second gate insulative film of the second p-channel MISFET and the semiconductor substrate.

This can optimize the concentration of the nitrogen introduced to the boundary between the each of the gate oxide films of four types of MISFETs of different conduction type and different gate oxide film thickness and compatibilize the reliability to the hot carriers and the reliability to the NBT.

The present invention also provides a semiconductor integrated circuit device manufactured by the method described above, in which a first n-channel MISFET and a first p-channel MISFET each having a first gate insulative film and a second n-channel MISFET and a second p-channel MISFET each having a second gate insulative film of a thickness larger than the first gate insulative film are formed on a main surface of a semiconductor substrate, and nitrogen is introduced to the boundary between the first and the second gate insulative films and the semiconductor substrate, wherein

the concentration of nitrogen introduced to the boundary between the second insulative film of the second n-channel MISFET and the semiconductor substrate is equal with or higher than the concentration of nitrogen introduced to the boundary between the first gate insulative film of the first n-channel MISFET and the semiconductor substrate, and

the concentration of nitrogen introduced to the boundary between the first insulative film of the first n-channel MISFET and the semiconductor substrate is higher than the concentration of nitrogen introduced to the boundary between the first gate insulative film of the first p-channel MISFET and the semiconductor substrate, and the concentration of nitrogen introduced to the boundary between the second gate insulative film of the second p-channel MISFET and the semiconductor substrate.

In the semiconductor integrated circuit device described above, wherein the gate electrodes of the first and the second n-channel MISFET are constituted including an n-polycrystal silicon film, and the gate electrodes of the first and the second p-channel MISFET are constituted including a p-polycrystal silicon film.

### DESCRIPTION OF THE ACCOMPANYING DRAWINGS

FIG. 1 is a cross sectional view for a main portion of a semiconductor substrate showing a method of manufacturing a logic LSI as a first embodiment according to the present invention;

FIG. 2 is a cross sectional view for a main portion of a semiconductor substrate showing a method of manufacturing a logic LSI as the first embodiment according to the present invention;

FIG. 3 is a cross sectional view for a main portion of a semiconductor substrate showing a method of manufacturing a logic LSI as the first embodiment according to the present invention;

FIG. 4 is a cross sectional view for a main portion of a semiconductor substrate showing a method of manufacturing a logic LSI as the first embodiment according to the present invention;

FIG. 5 is a cross sectional view for a main portion of a semiconductor substrate showing a method of manufacturing a logic LSI as the first embodiment according to the present invention;

FIG. 6 is a cross sectional view for a main portion of a semiconductor substrate showing a method of manufacturing a logic LSI as the first embodiment according to the present invention;

FIG. 7 is a cross sectional view for a main portion of a semiconductor substrate showing a method of manufacturing a logic LSI as the first embodiment according to the present invention;

FIG. 8 is a cross sectional view for a main portion of a semiconductor substrate showing a method of manufacturing a logic LSI as the first embodiment according to the present invention;

FIG. 9 is a cross sectional view for a main portion of a semiconductor substrate showing a method of manufacturing a logic LSI as the first embodiment according to the present invention;

FIG. 10 is a cross sectional view for a main portion of a semiconductor substrate showing a method of manufacturing a logic LSI as the first embodiment according to the present invention;

FIG. 11 is a cross sectional view for a main portion of a semiconductor substrate showing a method of manufacturing a logic LSI as the first embodiment according to the present invention;

FIG. 12 is a cross sectional view for a main portion of a semiconductor substrate showing a method of manufacturing a logic LSI as the first embodiment according to the present invention;

FIG. 13 is a cross sectional view for a main portion of a semiconductor substrate showing a method of manufacturing a logic LSI as the first embodiment according to the present invention;

FIG. 14 is a cross sectional view for a main portion of a semiconductor substrate showing a method of manufacturing a logic LSI as the first embodiment according to the present invention;

FIG. 15 is a cross sectional view for a main portion of a semiconductor substrate showing a method of manufacturing a logic LSI as the first embodiment according to the present invention;

FIG. 16 is a cross sectional view for a main portion of a semiconductor substrate showing a method of manufacturing a logic LSI as a second embodiment according to the present invention;

FIG. 17 is a cross sectional view for a main portion of a semiconductor substrate showing a method of manufacturing a logic LSI as the second embodiment according to the present invention;

FIG. 18 is a cross sectional view for a main portion of a semiconductor substrate showing a method of manufacturing a logic LSI as the second embodiment according to the present invention;

FIG. 19 is a cross sectional view for a main portion of a semiconductor substrate showing a method of manufacturing a DRAM embedded logic LSI as the second embodiment according to the present invention;

FIG. 20 is a cross sectional view for a main portion of a semiconductor substrate showing a method of manufacturing a logic LSI as the second embodiment according to the present invention;

FIG. 21 is a cross sectional view for a main portion of a semiconductor substrate showing a method of manufacturing a logic LSI as the second embodiment according to the present invention;

FIG. 22 is a cross sectional view for a main portion of a semiconductor substrate showing a method of manufacturing a logic LSI as the second embodiment according to the present invention;

FIG. 23 is a cross sectional view for a main portion of a semiconductor substrate showing a method of manufacturing a logic LSI as another embodiment according to the present invention;

FIG. 24 is a cross sectional view for a main portion of a semiconductor substrate showing a method of manufacturing a logic LSI as the second embodiment according to the present invention;

FIG. 25 is a cross sectional view for a main portion of a semiconductor substrate showing a method of manufacturing a logic LSI as the second embodiment according to the present invention;

FIG. 26 is a cross sectional view for a main portion of a semiconductor substrate showing a method of manufacturing a logic LSI as the second embodiment according to the present invention;

FIG. 27 is a cross sectional view for a main portion of a semiconductor substrate showing a method of manufacturing a logic LSI as the second embodiment according to the present invention;

FIG. 28 is a cross sectional view for a main portion of a semiconductor substrate showing a method of manufacturing a logic LSI as the second embodiment according to the present invention;

FIG. 29 is a cross sectional view for a main portion of a semiconductor substrate showing a method of manufacturing a logic LSI as the second embodiment according to the present invention;

FIG. 30 is a cross sectional view for a main portion of a semiconductor substrate showing a method of manufacturing a logic LSI as a third embodiment according to the present invention;

FIG. 31 is a cross sectional view for a main portion of a semiconductor substrate showing a method of manufacturing a logic LSI as the third embodiment according to the present invention;

FIG. 32 is a cross sectional view for a main portion of a semiconductor substrate showing a method of manufacturing a logic LSI as the third embodiment according to the present invention;

FIG. 33 is a cross sectional view for a main portion of a semiconductor substrate showing a method of manufacturing a logic LSI as the third embodiment according to the present invention;

FIG. 34 is a cross sectional view for a main portion of a semiconductor substrate showing a method of manufacturing a logic LSI as the third embodiment according to the present invention;

FIG. 35 is a cross sectional view for a main portion of a semiconductor substrate showing a method of manufacturing a logic LSI as the third embodiment according to the present invention;

FIG. 36 is a cross sectional view for a main portion of a semiconductor substrate showing a method of manufacturing a logic LSI as the third embodiment according to the present invention;

FIG. 37 is a cross sectional view for a main portion of a semiconductor substrate showing a method of manufacturing a logic LSI as the third embodiment according to the present invention;

FIG. 38 is a cross sectional view for a main portion of a semiconductor substrate showing a method of manufacturing a logic LSI as the third embodiment according to the present invention;

FIG. 39 is a cross sectional view for a main portion of a semiconductor substrate showing a method of manufacturing a logic LSI as the third embodiment according to the present invention;

FIG. 40 is a cross sectional view for a main portion of a semiconductor substrate showing a method of manufacturing a logic LSI as a fourth embodiment according to the present invention;

FIG. 41 is a cross sectional view for a main portion of a semiconductor substrate showing a method of manufacturing a logic LSI as the fourth embodiment according to the present invention;

FIG. 42 is a cross sectional view for a main portion of a semiconductor substrate showing a method of manufacturing a logic LSI as the fourth embodiment according to the present invention;

FIG. 43 is a cross sectional view for a main portion of a semiconductor substrate showing a method of manufacturing a logic LSI as the fourth embodiment according to the present invention;

FIG. 44 is a cross sectional view for a main portion of a semiconductor substrate showing a method of manufacturing a logic LSI as the fourth embodiment according to the present invention;

FIG. 45 is a cross sectional view for a main portion of a semiconductor substrate showing a method of manufacturing a logic LSI as the fourth embodiment according to the present invention;

FIG. 46 is a cross sectional view for a main portion of a semiconductor substrate showing a method of manufacturing a logic LSI as the fourth embodiment according to the present invention;

FIG. 47 is a cross sectional view for a main portion of a semiconductor substrate showing a method of manufacturing a logic LSI as the fourth embodiment according to the present invention;

FIG. 48 is a cross sectional view for a main portion of a semiconductor substrate showing a method of manufacturing a logic LSI as the fourth embodiment according to the present invention; and

FIG. 49 is a cross sectional view for a main portion of a semiconductor substrate showing a method of manufacturing a logic LSI as the fourth embodiment according to the present invention.

### DESCRIPTION OF PREFERRED EMBODIMENTS

The present invention is to be described specifically by way of preferred embodiments with reference to the drawings. Throughout the drawings for explaining the preferred embodiments, those portions and components having identical functions carry same reference numerals, for which duplicate descriptions will be omitted.

(Embodiment 1)

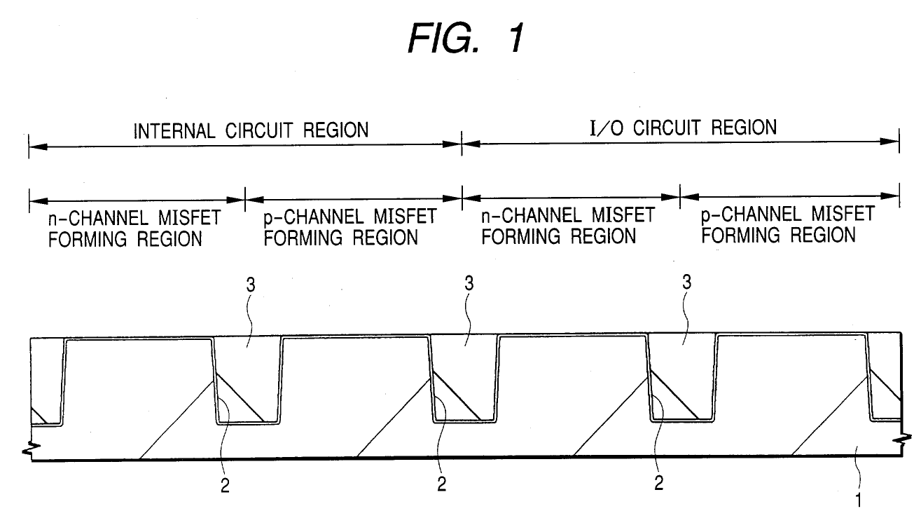

A method of manufacturing a CMOS-LSI according to this embodiment is to be described in the sequence of steps with reference to FIG. 1 to FIG. 15. In each of the drawings showing the method of manufacturing the CMOS-LSI, a region on the left shows an internal circuit region and a region on the right shows an I/O (input/output) circuit region in the drawing. Further, the left for each of the internal circuit region and the I/O circuit region shows an n-channel MISFET forming region, and the right thereof shows a p-channel MISFET forming region.

In the CMOS-LSI of this embodiment, MISFETs constituting the internal circuit are operated at a low voltage with a view point of reducing the consumption power of the circuit. For this purpose, the gate oxide film for each of the n-channel MISFET and the p-channel MISFET is constituted with a reduced thickness. On the other hand, in the gate oxide film of the n-channel MISFET and the p-channel MISFET in the I/O circuit applied with a high external voltage, the gate oxide film for each of them is constituted with a large thickness with a view point of ensuring voltage withstanding of the gate.

At first, as shown in FIG. 1, a device isolation trench 2 is formed to a p-type single crystal silicon substrate (hereinafter referred to as a substrate) having a specific resistivity, for example, of about 1 to 10 Ωcm. The device isolation trench 2 is formed by etching the substrate 1 in a device isolation region to form a trench, then depositing a silicon oxide film 3 on the substrate 1 including the inside of the trench by a CVD method and, successively, removing the silicon oxide film 3 outside of the trenches by a chemical mechanical polishing method.

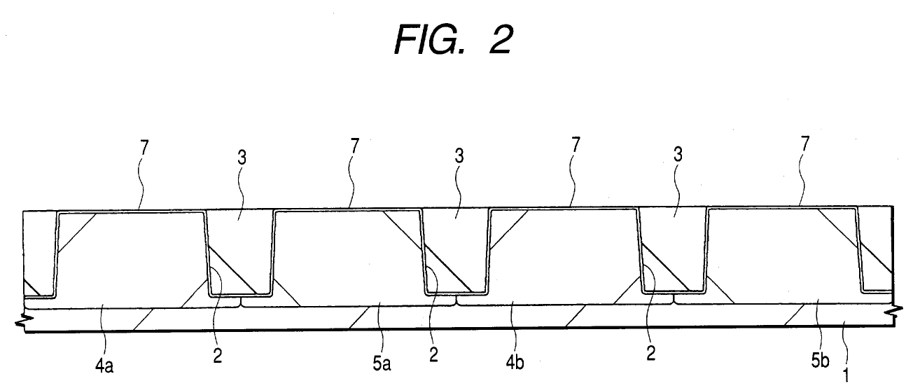

Then, as shown in FIG. 2, the substrate 1 is wet-oxidized to form a thin silicon oxide film 7 of 10 nm or less on the surface thereof. Successively, boron is ion implanted to a portion of the substrate 1 through the silicon oxide film 7 and ion implanting phosphorus to other portion and then the substrate 1 is applied with a heat treatment to diffuse the impurities (boron and phosphorus) to the inside of the substrate 1, thereby forming a p-wells 4a, 4b in the n-channel MISFET forming region and forming n-wells 5a, 5b in the p-channel MISFET forming region. Further, in this process, for controlling the threshold voltage of MISFET, boron is ion implanted to the surface of the p-wells 4a, 4b (channel forming region), while phosphorus is ion implanted to the surface of the n-wells 5a, 5b (channel forming region).

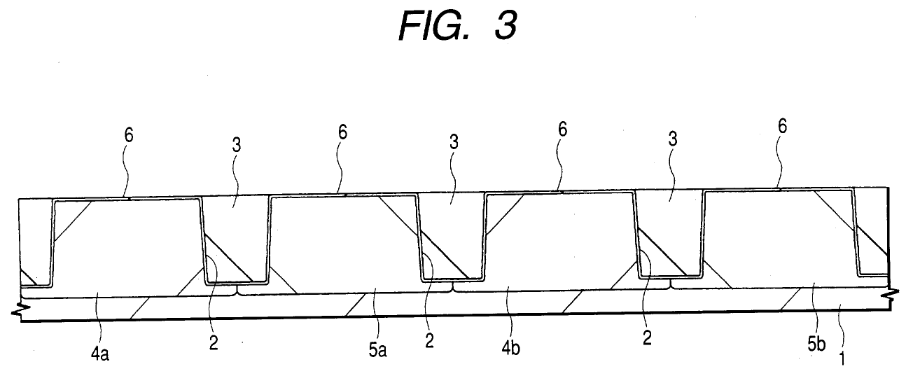

Then, after removing the silicon oxide film 7 on the surface of the substrate 1 with hydrofluoric acid, the substrate 1 is wet oxidized as shown in FIG. 3 to form a silicon oxide film 6 of about 4 nm thickness to the surface for each of the p-wells 4a, 4b and the n-wells 5a, 5b. The silicon oxide film 6 constitutes a portion of a thick gate oxide film to be formed in the internal circuit region in the subsequent step.

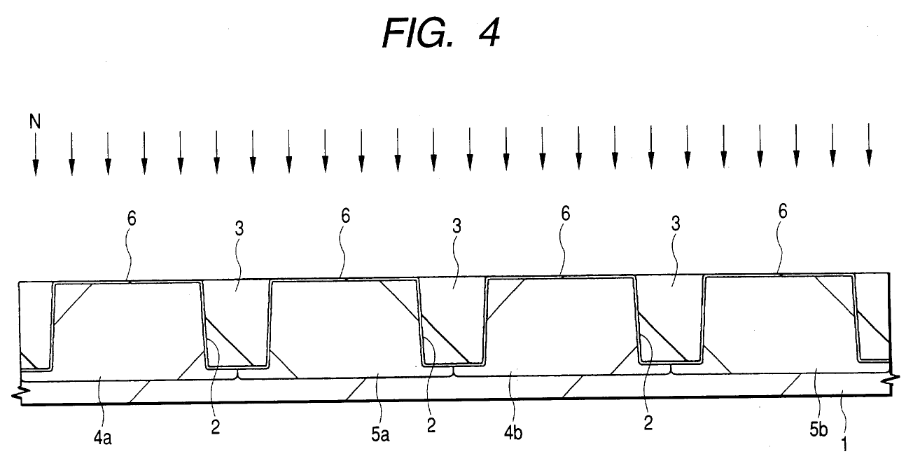

Then, as shown in FIG. 4, nitrogen is introduced by a predetermined amount (for example, about 2%) near the boundary between the silicon oxide film 6 and the substrate 1 by applying a heat treatment (oxynitridation processing) to the substrate 1 in an atmosphere containing NO (nitrogen monoxide). In this case, the concentration of nitrogen introduced near the boundary between the silicon oxide film 6 and the substrate 1 is identical for the entire substrate 1.

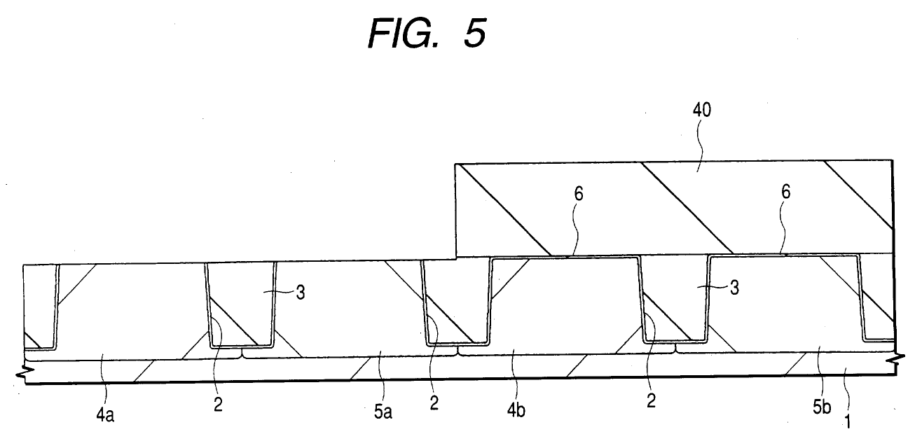

Then, as shown in FIG. 5, the surface of the substrate 1 of the I/O circuit region is covered with a photoresist film 40 and the surface of the substrate 1 in the internal circuit region is etched by hydrofluoric acid to remove the silicon oxide film 6. By the etching, since nitrogen introduced near the boundary between the silicon oxide film 6 and the substrate 1 in the internal circuit region is removed together with the silicon oxide film 6, the nitrogen concentration in the region is reduced to about 0%.

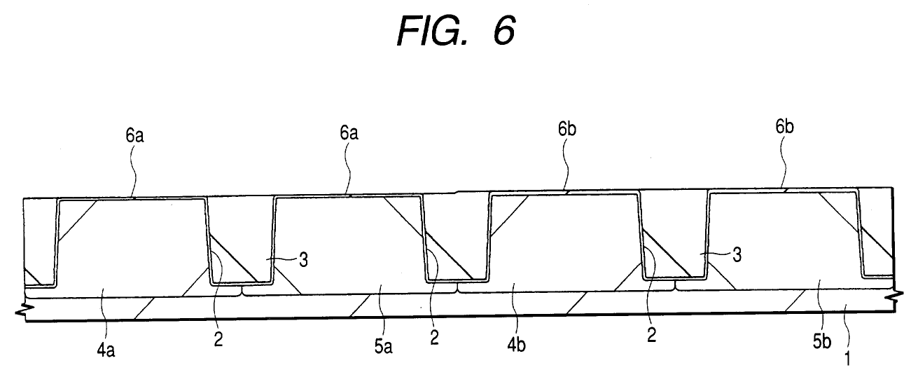

Then, after removing the photoresist film 40, as shown in FIG. 6, the substrate 1 is wet-oxidized to form a gate oxide film 6a of about 2 nm thickness on the surface of the substrate 1 in the internal circuit region (p-well 4a, n-well 5a). Since the surface of the substrate 1 in the I/O circuit region (p-well 4b and n-well 5b) is also oxidized in this step, a gate oxide film 6b containing the silicon oxide film 6 as a portion thereof and having a larger thickness (about 6 nm) than that of the silicon oxide film 6 is formed on the surface of the substrate 1 in this region.

By the steps so far described above, the gate oxide film 6a of a reduced thickness (about 2 nm) on the surface of the substrate 1 in the internal circuit region (p-well 4a and n-well 5a), while a gate oxide film 6b of a large thickness (about 6 nm) is formed on the surface of the substrate 1 in the I/O circuit region (p-well 4b and n-well 5b).

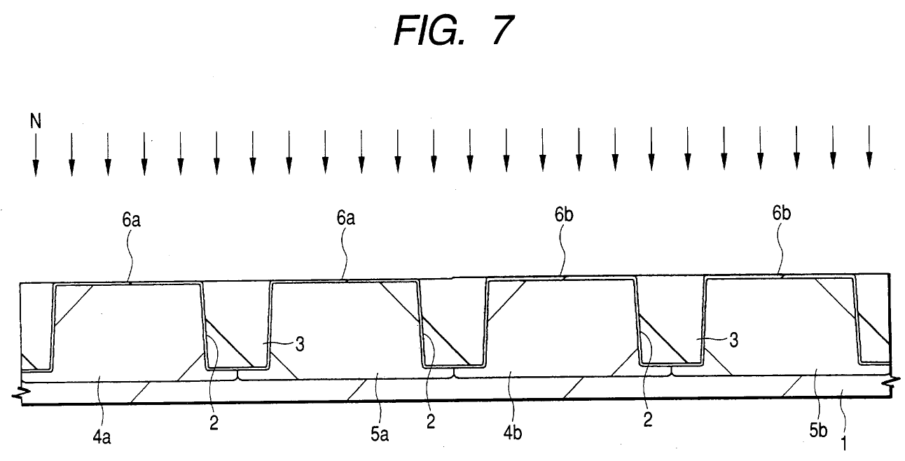

Then, as shown in FIG. 7, nitrogen is introduced by a predetermined amount near the boundary between the gate oxide films 6a, 6b and the substrate 1 by applying a heat treatment to the substrate 1 (oxynitridation processing) in an atmosphere containing NO.

When the second oxynitridation processing is conducted, the concentration of nitrogen introduced through the thin gate oxide film 6a in the internal circuit region (p-well 4a and n-well 5a) to the substrate 1 is controlled to about 2%. In this case, the concentration of nitrogen introduced through the thick gate oxide film 6b in the I/O circuit region (p-well 4b and n-well 5b) to the substrate 1 is about 1/10 for the concentration of nitrogen introduced to the substrate 1 in the internal circuit region (p-well 4a and n-well 5a), that is, about 0.2%.

As described above, nitrogen at about 2% has been introduced by the first oxynitridation processing near the boundary between the thick gate oxide film 6b in the I/O circuit region and the substrate 1 (p-well 4b and n-well 5b). Accordingly, at the instance of applying the second oxynitridation processing, the concentration of nitrogen near the boundary between the thick gate oxide film 6b in the I/O circuit region and the substrate 1 (p-well 4b and n-well 5b) is about 2.2%. On the other hand, nitrogen introduced to the substrate 1 (p-well 4a and n-well 5a) in the internal circuit region by the first oxynitridation processing has been almost removed by etching conducted between the first oxynitridation processing and the second oxynitridation processing. Accordingly, the concentration of nitrogen near the boundary between the thin gate oxide film 6a in the internal circuit region and the substrate 1 (p-well 4a and n-well 5a) at the instance of applying the second oxynitridation processing is about 2%. That is, by the steps so far described above, the concentration of nitrogen near the boundary between the thick gate oxide film 6b in the I/O circuit region and the substrate 1 (p-well 4b and n-well 5b) (=about 2.2%) is higher than the nitrogen concentration near the boundary between the thin gate oxide film 6a in the internal circuit region and the substrate 1 (p-well 4a and n-well 5a) (=about 2%).

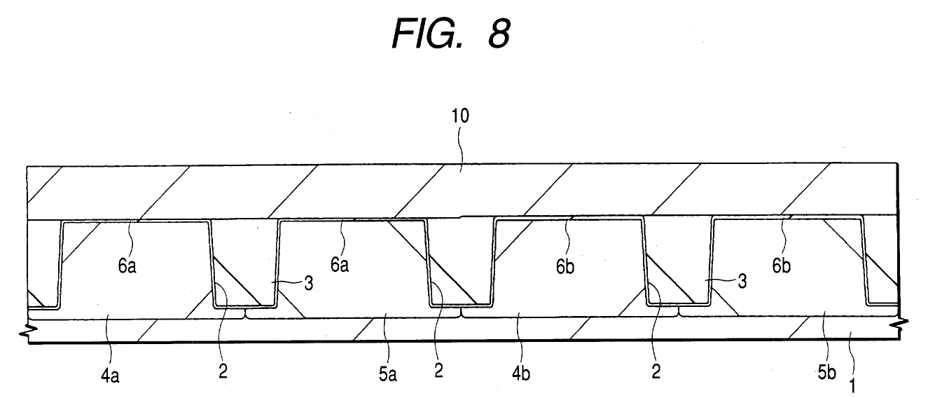

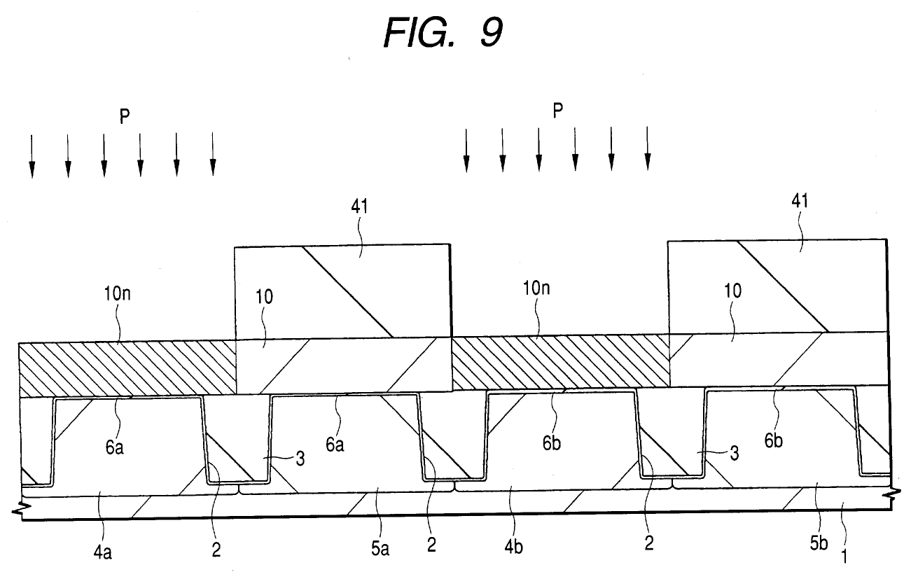

Then, as shown in FIG. 8, a non-doped polycrystal silicon film 10 is deposited on the substrate 1 by a CVD method. Successively, as shown in FIG. 9, the polycrystal silicon film 10 above the p-channel MISFET forming region, that is, n-wells 5a, 5b is covered with a photoresist film 41, and phosphorus or arsenic is ion implanted to the polycrystal silicon film 10 above the n-channel MISFET forming region, that is, p-wells 4a, 4b, thereby converting the polycrystal silicon film 10 in the region into an n-polycrystal silicon film 10n at low resistivity.

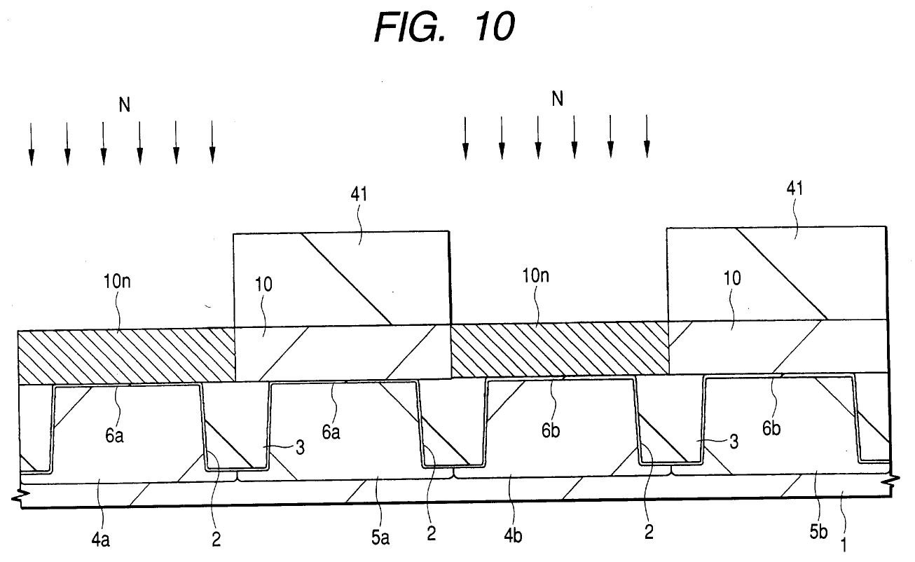

Then, as shown in FIG. 10, nitrogen (N₂⁺) is ion implanted through the n-polycrystal silicon film 10n to the boundary between the gate oxide film 6a and the p-well 4a and to the boundary between the gate oxide film 6b and the p-well 4b therebelow. In this case, nitrogen corresponding to the concentration at about 2% is introduced near the boundary by controlling the dose of nitrogen, for example, to 5×10¹⁴/cm².

As described above, nitrogen at about 2.2% has been introduced near the boundary between the thick gate oxide film 6b in the I/O circuit region and the substrate 1 (p-well 4b and n-well 5b) by the twice oxynitridation processings described above. Further, nitrogen at about 2% is introduced near the boundary between the thin gate oxide film 6a in the internal circuit region and the substrate 1 (p-well 4a and n-well 5a).

Accordingly, the nitrogen concentration near the boundary between the thick gate oxide film 6b in the I/O circuit region and the p-well 4b is about 4.2% and the concentration of nitrogen near the boundary between the thin gate oxide film 6a in the internal circuit region and the p-well 4a is about 4% by conducting nitrogen ion implantation to the p-wells 4a, 4b.

Since the portions above the p-channel MISFET forming region, that is, each of the n-well 5a in the internal circuit region and the n-well 5b in the I/O circuit region are covered with the photoresist film 41, the concentration of nitrogen is not increased by the ion implantation of nitrogen described above. That is, the concentration of nitrogen near the boundary between the thick gate oxide film 6b and the n-well 5b in the I/O circuit region is about 2.2%, and the concentration of nitrogen near the boundary between the thin gate oxide film 6a and the n-well 5a in the internal circuit region is about 2%.

By the steps so far described above, the concentration of nitrogen introduced near the boundary between the gate oxide film and the substrate (well) is highest, that is, at about 4.2% for the n-channel MISFET forming region (p-well 4b) in the I/O circuit region, and successively, at about 4% for the n-channel MISFET forming region (p-well 4a) in the internal circuit region, at about 2.2% for the p-channel MISFET forming region (n-well 5b) in the I/O circuit region, and at about 2% for the p-channel MISFET forming region (n-well 5a) in the internal circuit region.

In the steps described above, phosphorus or arsenic is ion implanted into the polycrystal silicon film 10 to convert the same into the n-polycrystal silicon film 10n and then nitrogen is ion implanted through the n-polycrystal silicon film 10n to the p-wells 4a, 4b. On the contrary, nitrogen may be ion implanted through the polycrystal silicon film 10 to the p-wells 4a, 4b and then phosphorus or arsenic may be ion implanted into the polycrystal silicon film 10 to convert the same into the n-polycrystal silicon film 10n.

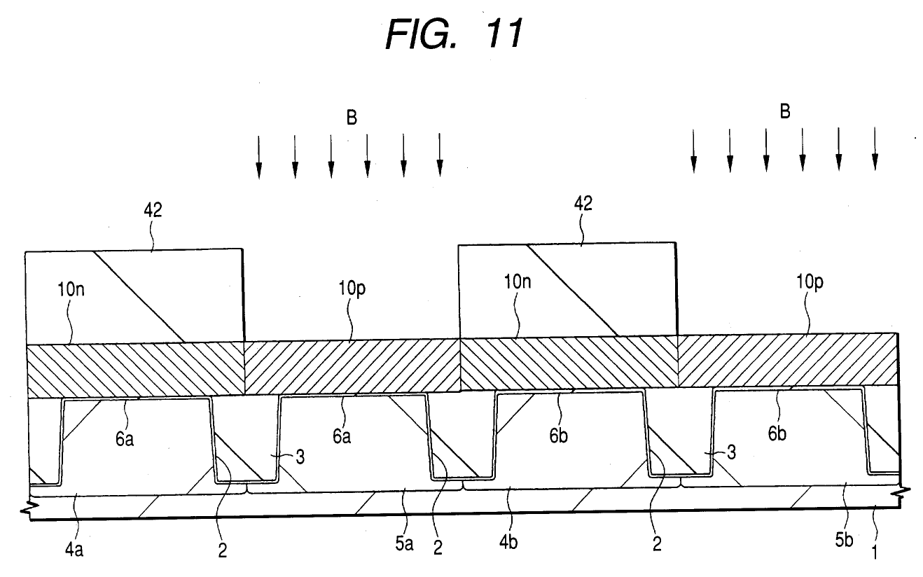

Then, after removing the photoresist film 41, as shown in FIG. 11, the n-polycrystal silicon film 10n above the n-channel MISFET forming region (p-wells 4a, 4b) is covered with a photoresist film 41 and boron is ion implanted to the polycrystal silicon film 10 above the p-channel MISFET forming region (n-wells 5a, 5b), thereby converting the polycrystal silicon film 10 in the region into a p-polycrystal silicon film 10p of low resistivity. The sequence of the steps so far may be partially modified such that the polycrystal silicon film 10 above the n-wells 5a, 5b is converted into the p-polycrystal silicon film 10p and then the polycrystal silicon film 10 above the p-wells 4a, 4b may be converted into the n-polycrystal silicon film 10n or nitrogen may be ion implanted to the p-wells 4a, 4b.

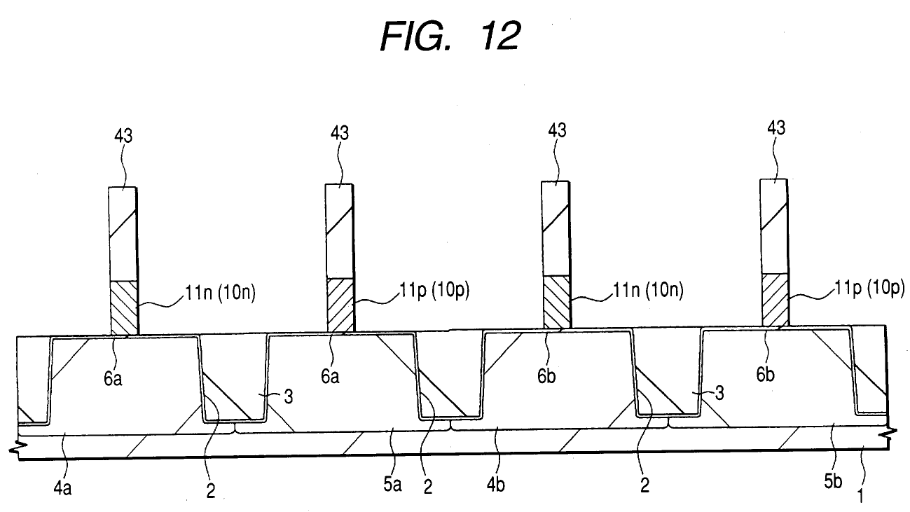

Then, after removing the photoresist film 42, as shown in FIG. 12, the n-polycrystal silicon film 10n and the p-polycrystal silicon film 10p are dry etched by using a photoresist film 43 as a mask thereby forming a gate electrode 11n comprising the n-polycrystal silicon film 10n above the p-wells 4a, 4b and a gate electrode 11p comprising the p-polycrystal silicon film 10p above the n-wells 5a, 5b.

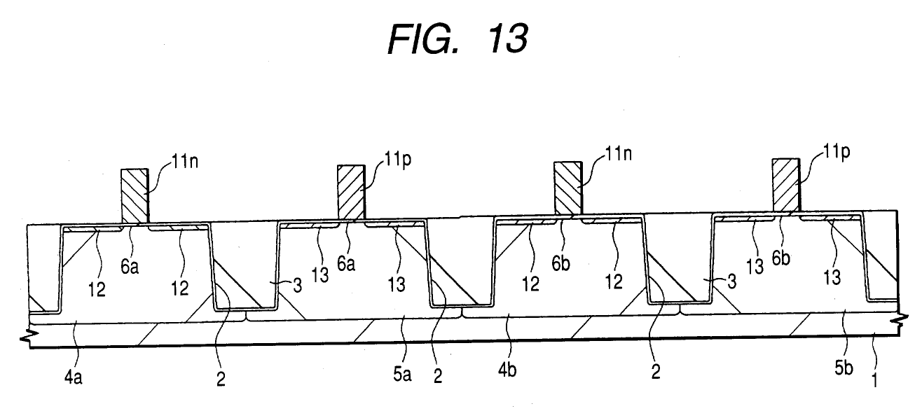

Then, after removing the photoresist 43, as shown in FIG. 13, n⁻-semiconductor regions 12 are formed to the p-wells 4a, 4b, and p⁻-semiconductor regions 13 are formed to the n-wells 5a, 5b. The n⁻-semiconductor regions 12 are formed by covering the n-wells 5a, 5b with a photoresist film (not illustrated), and ion implanting phosphorus or arsenic to the p-wells 4a, 4b. Further, the p⁻-semiconductor regions 13 are formed by covering the p-wells 4a, 4b with a photoresist film (not illustrated), and ion implanting boron into the n-wells 5a, 5b. The n⁻-semiconductor regions 12 are formed for making the source and drain of the n-channel MISFET into an LDD (Lightly Doped Drain) structure, while the p⁻-semiconductor regions 13 are formed for making the source and drain of the p-channel MISFET into the LDD structure.

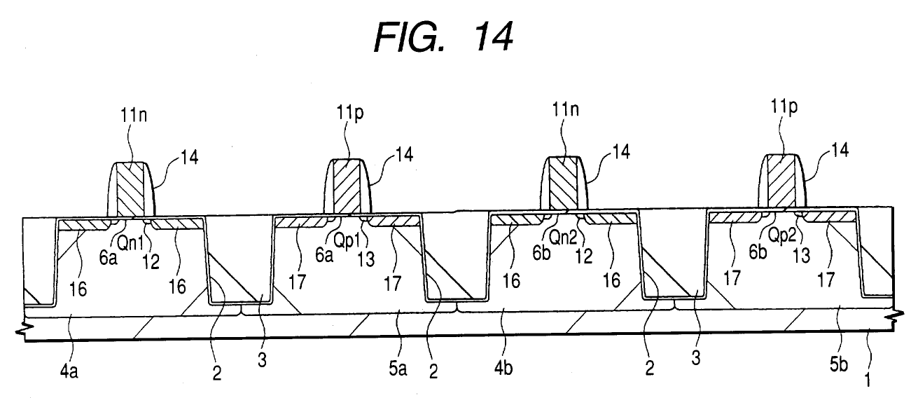

Then, as shown in FIG. 14, side wall spacers 14 are formed to the side walls of the gate electrodes 11n, 11p. The side wall spacers 14 are formed by depositing a silicon nitride film on the substrate 1 by a CVD method and, successively, anisotropically etching the silicon nitride film to leave the gate electrode 11n, 11- on the side walls.

Then, n⁺-semiconductor regions (source, drain) 16 are formed to the p-wells 4a, 4b, and p⁺-semiconductor regions (source, drain) 17 are formed to the n-wells 5a, 5b. The n⁺-semiconductor regions (source, drain) 16 are formed by covering the n-wells 5a, 5b with a photoresist film (not illustrated) and ion implanting phosphorus or arsenic to the p-wells 4a, 4b. Further, the p⁺-semiconductor regions (source, drain) 17 are formed by covering the p-wells 4a, 4b with a photoresist film (not illustrated) and ion implanting boron to the n-wells 5a, 5b.

By the steps so far described, the n-channel MISFET having the thin gate oxide film 6a (Qn1) is formed to the p-well 4a in the internal circuit region, and the n-channel MISFET having the thick gate oxide film 6b (Qn2) is formed to the p-well 4b in the I/O circuit region. Further, the p-channel MISFET having the thin gate oxide film 6a (Qp1) is formed to the n-well 5a in the internal circuit region, and the p-channel MISFET having the thick gate oxide film 6b (Qp2) is formed to the n-well 5b in the I/O circuit region.

Then, the concentration of the nitrogen introduced near the boundary between the gate oxide film and the substrate (well) is given as: n-channel MISFET in the I/O circuit region (Qn2)>n-channel MISFET in the internal circuit region (Qn1)>p-channel MISFET in the I/O circuit region (Qp2)>p-channel MISFET in the internal circuit region (Qp1) in the order of higher concentration.

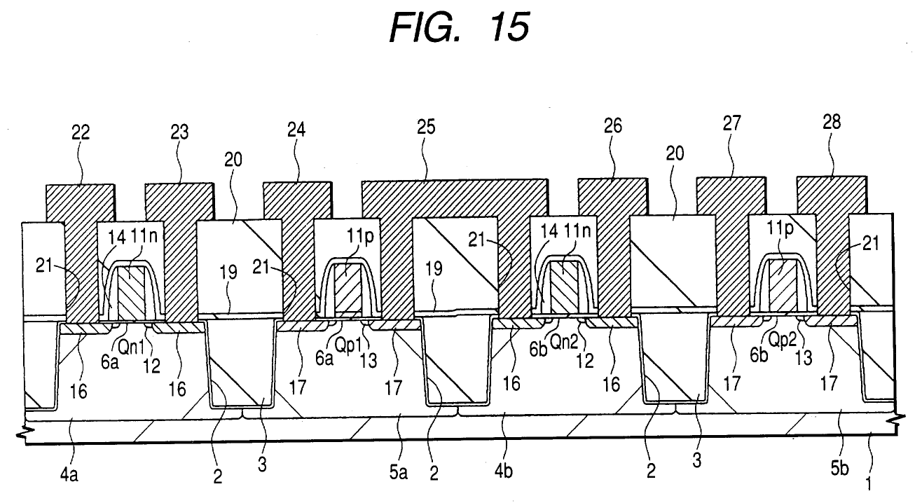

Then, as shown in FIG. 15, a silicon nitride film 19 is deposited on the substrate 1 by a CVD method, successively, a silicon oxide film 20 is deposited on the silicon nitride film 19 by a CVD method and then the silicon oxide film 20 and the silicon nitride film 19 are dry etched by using a photoresist film (not illustrated) formed on the silicon oxide film 20 as a mask, thereby forming contact holes 21 above the n⁺-semiconductor regions (source, drain) 16 and above the p⁺-semiconductor regions (source, drain) 17, respectively.

Then, tungsten wirings 22 to 28 are formed above the silicon oxide film 20 by depositing a tungsten (W) film on the silicon oxide film 20 including the inside of the contact holes 21 by a CVD method or a sputtering method and, successively, dry etching the tungsten film by using a photoresist film (not illustrated) as a mask. Then, metal wirings in plural layers are formed on the tungsten wirings 22 to 28 by way of an interlayer insulative film, but they are not illustrated.

As described above, according to this embodiment, since nitrogen is introduced to the boundary between the gate oxide film 6a and the p-well 4a of the n-channel MISFET (Qn1) and to the boundary between the gate oxide film 6b and the p-well 4b of the n-channel MISFET (Qn2), the hot carrier endurance of the n-channel MISFET (Qn1, Qn2) can be improved. Further, by increasing the concentration of nitrogen higher in the n-channel MISFET (Qn2) having the thick gate oxide film 6b, the hot carrier durability of the n-channel MISFET (Qn2) tending to cause deterioration in the reliability due to hot carriers can be improved reliably.

Further, according to this embodiment, deterioration of the reliability of the p-channel MISFET (Qp1, Qp2) tending to cause more deterioration in the reliability due to NBT compared with the n-channel MISFET (Qn1, Qn2) can be suppressed by lowering the concentration of nitrogen introduced to the boundary between the gate oxide film 6a and the n-well 5a of the p-channel MISFET (Qp1), and to the boundary between the gate oxide film 6b and the n-well 5b of the p-channel MISFET (Qp2) than that in the n-channel MISFET (Qn1, Qn2).

That is, according to this embodiment, it is possible to compatibilize the reliability to hot carriers and the reliability to NBT by optimizing the concentration of nitrogen introduced to the boundary between the gate oxide films of four types of MISFET (Qn1, Qn2, Qp1, Qp2) of different conduction type and different gate oxide film thickness, and the substrate (well).

Further, according to this embodiment, fluctuation of the device characteristics caused by leakage of boron in the p-polycrystal silicon film 10p constituting the gate electrode lip of the p-channel MISFET (Qp1, Qp2) to the substrate 1 can be suppressed by introducing nitrogen to the boundary between the gate oxide film 6a and the n-well 5a of the p-channel MISFET (Qp1) and to the boundary between the gate oxide film 6b and the n-well 5b of the p-channel MISFET (Qp2).

Further, according to this embodiment, since no photomask is added upon introduction of nitrogen, the foregoing effects can be obtained while minimizing the increase in the manufacturing cost.

(Embodiment 2)

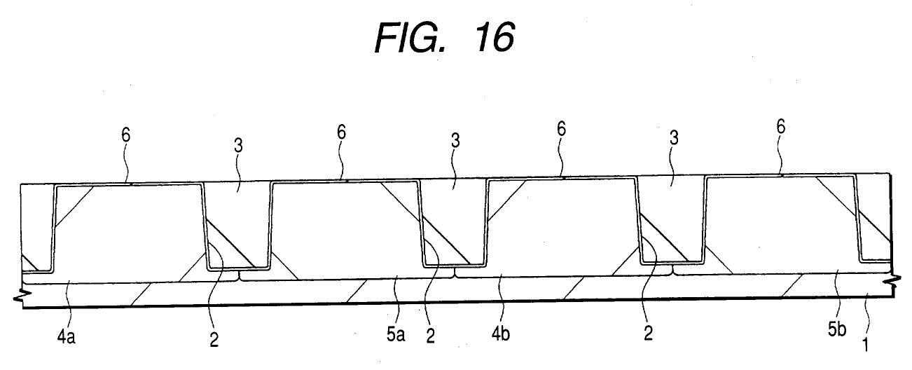

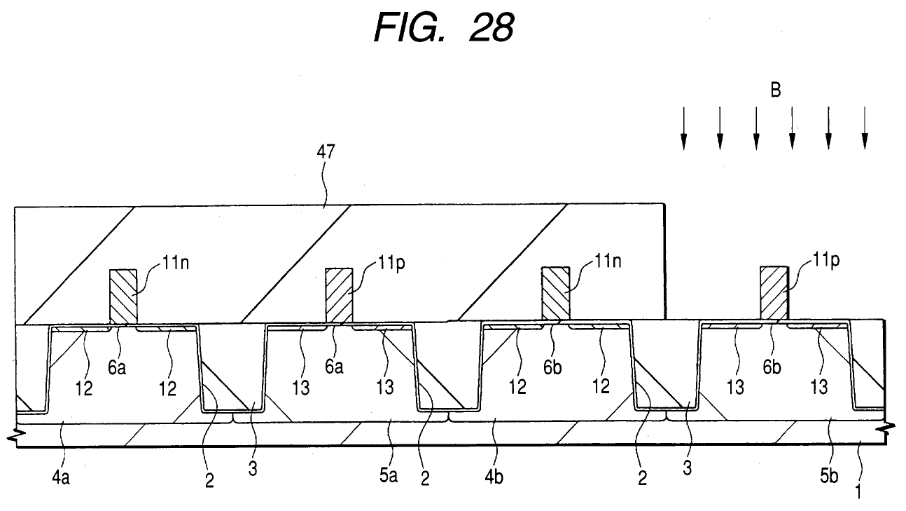

A method of manufacturing a CMOS-LSI according to this embodiment is to be described in the sequence of steps with reference to FIG. 16 to FIG. 29. In the same manner as in Embodiment 1 described above, region on the left to the center shows an internal circuit region and the region on the right to the center shows an I/O (input/output) circuit region in each of the drawings. Further, the left part for each of the internal circuit region and the I/O circuit region shows an n-channel MISFET forming region, and the right part thereof shows a p-channel MISFET forming region.

At first, as shown in FIG. 16, device isolation trenches 2, p-wells 4a, 4b and n-wells 5a, 5b are formed to a substrate 1 and, successively, a silicon oxide film 6 of about 4 nm thickness is formed to the surface for each of the p-wells 4a, 4b and n-wells 5a, 5b. The steps so far described above are identical with the steps shown in FIG. 1 to FIG. 3 for the Embodiment 1 described above.

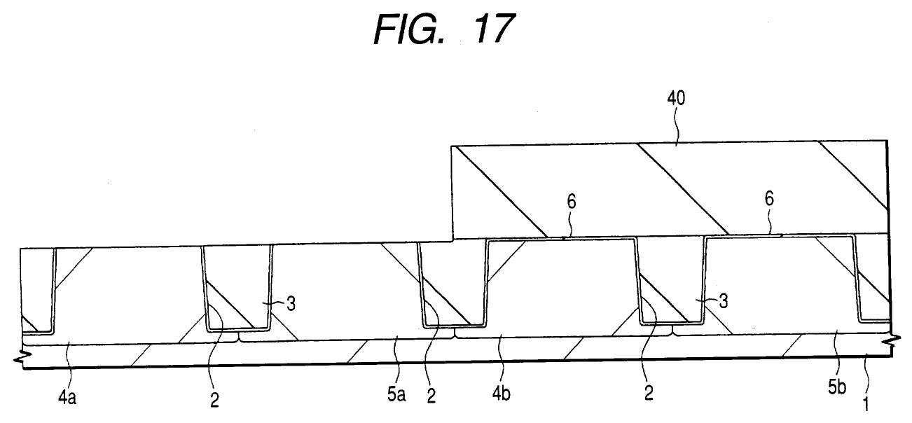

Then, as shown in FIG. 17, the surface of the substrate 1 in the I/O circuit region is covered with a photoresist 40 and the surface of the substrate 1 in the internal circuit region is etched by hydrochloric acid to remove the silicon oxide film 6 in the region.

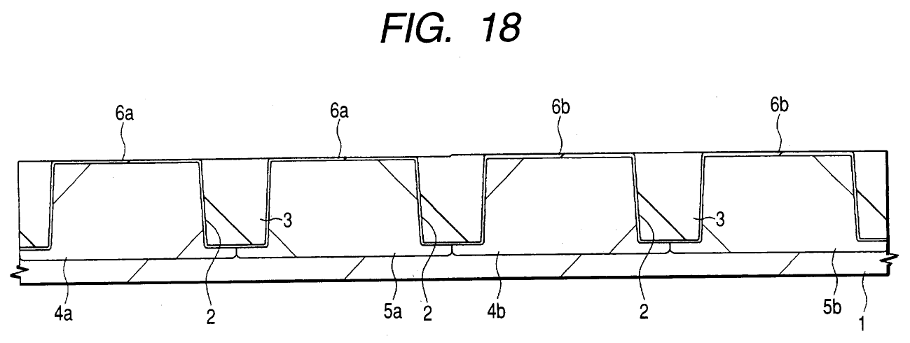

Then, after removing the photoresist film 40, as shown in FIG. 18, the substrate 1 is wet-oxidized to form a thin gate oxide film 6a of about 2 nm thickness to the surface of the substrate 1 in the internal circuit region (p-well 4a and n-well 5a). In this step, since the surface of the substrate 1 in the I/O circuit region (p-well 4b and n-well 5b) is also oxidized, a gate oxide film 6b of a large thickness (about 6 nm) containing the silicon oxide film 6 as a portion thereof is formed on the surface of the substrate 1 in the I/O circuit region.

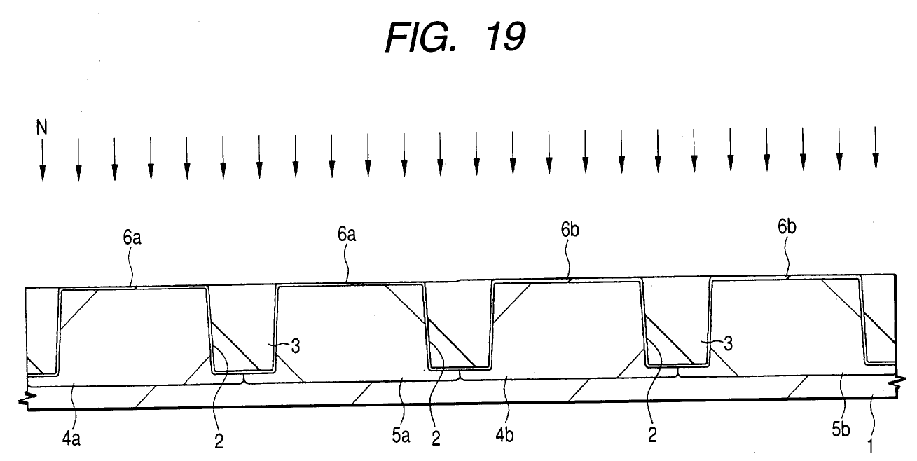

Then, as shown in FIG. 19, a heat treatment (oxynitridation processing) is applied to the substrate 1 in an atmosphere containing NO to introduce nitrogen near the boundary between the gate oxide films 6a, 6b and the substrate 1. In this case, when the nitrogen concentration introduced through the thin gate oxide film 6a of the internal circuit region to the substrate 1 (p-well 4a and n-well 5a) is controlled to about 2%, the concentration of nitrogen introduced through the thick gate oxide film 6b to the substrate 1 in the I/O circuit region (p-well 4b and n-well 5b) is about 0.2%.

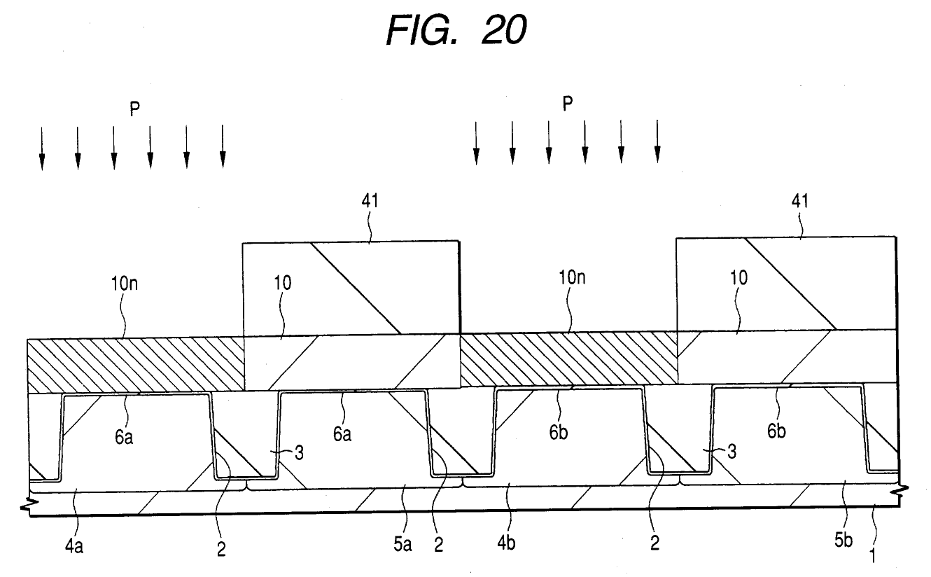

Then, as shown in FIG. 20, after depositing a non-doped polycrystal silicon oxide film 10 on the substrate 1 by a CVD method, the polycrystal silicon film 10 on the p-channel MISFET forming region (n-wells 5a, 5b) is covered with a photoresist film 41, and phosphorus or arsenic is ion implanted to the polycrystal silicon film 10 above the n-channel MISFET forming region (p-wells 4a, 4b), thereby converting the polycrystal silicon film 10 in the region into an n-polycrystal silicon film 10n of low resistivity.

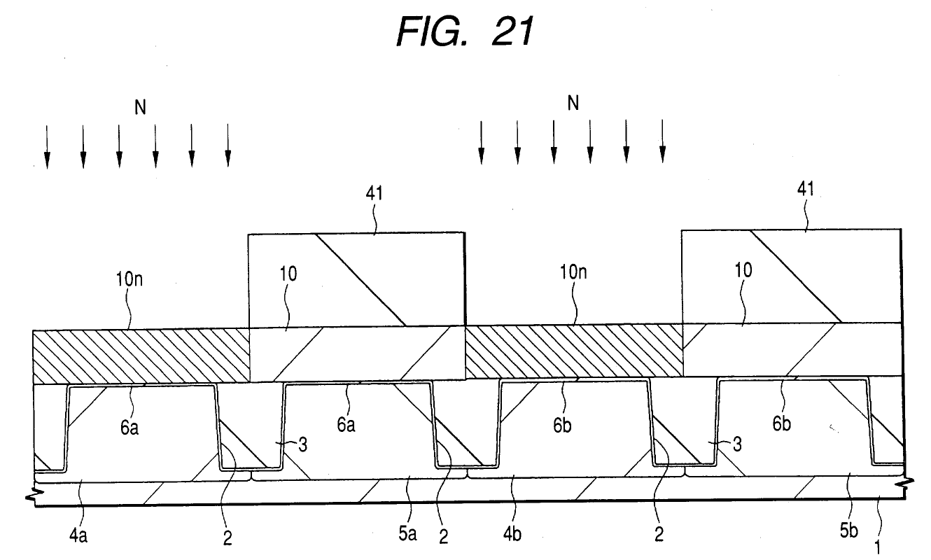

Then, as shown in FIG. 21, while leaving the photoresist film 41 on the polycrystal silicon film 10 in the p-channel MISFET forming region (n-wells 5a, 5b), nitrogen (N₂⁺) is ion implanted through the n-polycrystal silicon film 10n to the boundary between the gate oxide film 6a and the p-well 4a and to the boundary between the gate oxide film 6b and the p-well 4b therebelow. In this case, nitrogen corresponding to the concentration of about 2% is introduced near the boundary by controlling the dose of nitrogen, for example, 5×10¹⁴/cm².

As described above, nitrogen atom of about 2% is introduced near the boundary between the thin gate oxide film 6a in the internal circuit region (p-well 4a and n-well 5a) and the substrate 1, and nitrogen of about 0.2% is introduced near the boundary between the thick gate oxide film 6b in the I/O circuit region (p-well 4b and n-well 5b) and the substrate 1 in the oxynitridation processing.

Then, since nitrogen at about 2% is further introduced by the nitrogen ion implantation in the step described above, the concentration of nitrogen near the boundary between the thin gate oxide film 6a and the p-well 4a in the internal circuit region is about 4%, and the concentration of nitrogen near the boundary between the thick gate oxide film 6b and the p-well 4b in the I/O circuit region is about 2.2%.

On the other hand, since a portion above each of the n-well 5a in the internal circuit region and the n-well 5b in the I/O circuit region is covered with the photoresist 41, concentration of nitrogen in the nitrogen ion implantation step described above is not increased. That is, the concentration of nitrogen near the boundary between the thin gate oxide film 6a and the n-well 5a in the internal circuit region is about 2%, while the concentration of nitrogen near the boundary between the thick gate oxide film 6b and the n-well 5b in the I/O circuit region is about 0.2%.

The concentration of nitrogen introduced to the boundary between the gate oxide film and the substrate (well) by the steps so far described above is higher in the n-channel MISFET forming region (p-wells 4a, 4b) than in the p-channel MISFET forming region (n-wells 5a, 5b). However, at the instance, the concentration of nitrogen (about 4%) near the boundary between the thin gate oxide film 6a and the p-well 4a is higher than the concentration of nitrogen (about 2.2%) near the boundary between the thick gate oxide film 6b and the p-well 4b.

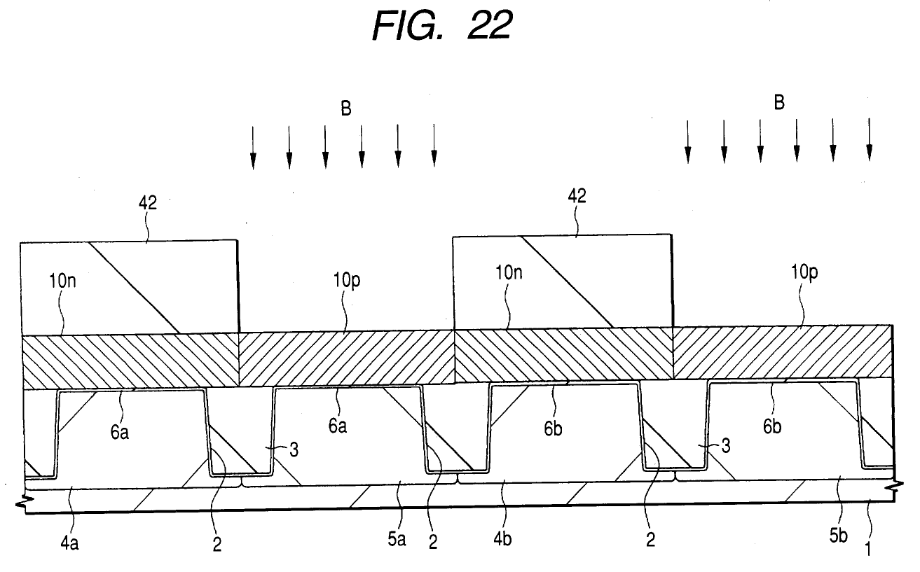

Then, after removing the photoresist film 41, as shown in FIG. 22, the n-polycrystal silicon film 10n above the n-channel MISFET forming region (p-wells 4a, 4b) is covered with a photoresist film 42 and boron is ion implanted to the polycrystal silicon film 10 above the p-channel MISFET forming region (n-wells 5a, 5b), thereby converting the polycrystal silicon film 10 in the region into a p-polycrystal silicon film 10p of low resistivity.

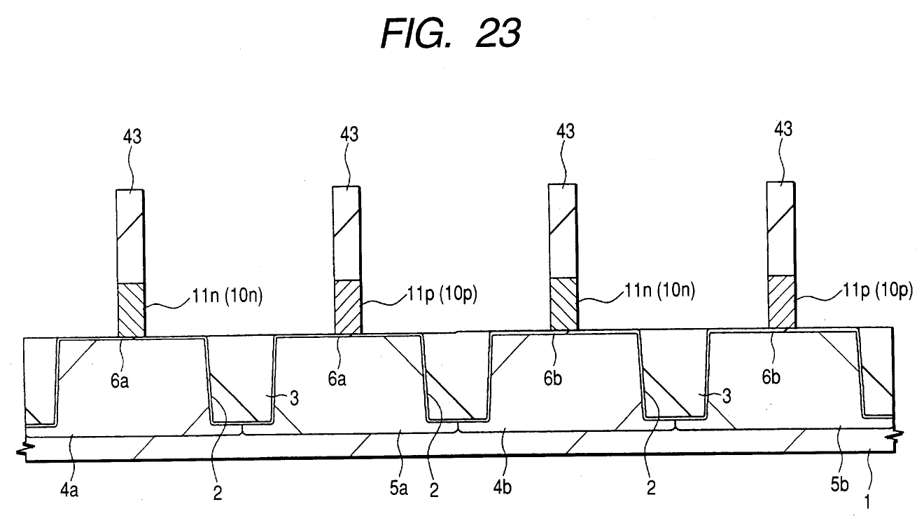

Then, after removing the photoresist film 42 as shown in FIG. 23, the n-polycrystal silicon film 10n and the p-polycrystal silicon film 10p are dry etched by using the photoresist film 43 as a mask, thereby forming gate electrodes 11n comprising the n-polycrystal silicon film 10n above the p-wells 4a, 4b, and gate electrodes 11p comprising the p-polycrystal silicon film 10p above the n-wells 5a, 5b.

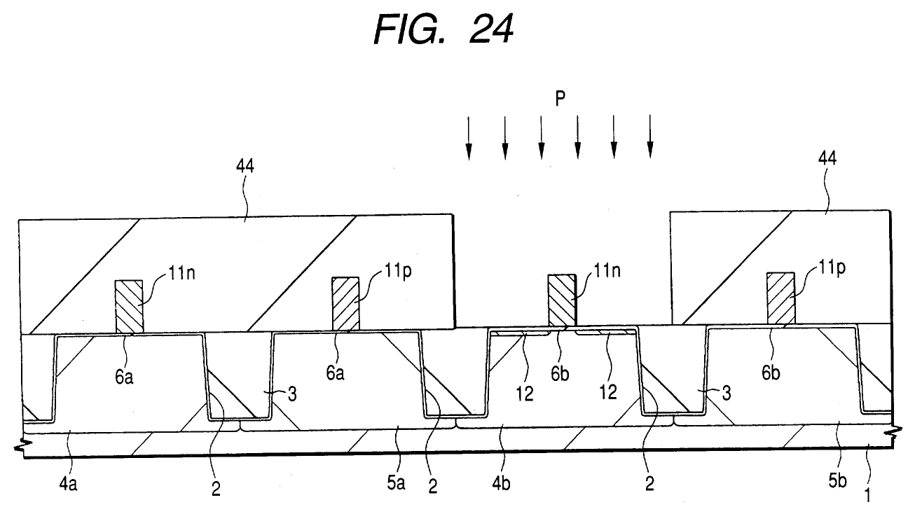

Then, as shown in FIG. 24 after removing the photoresist film 43, a photoresist film 44 opened at the portion above the p-well 4b is formed above the substrate 1, and phosphorus or arsenic is ion implanted to the p-well 4b using the photoresist film 44 as a mask, thereby forming n⁻-semiconductor regions 12. As has been described above, the n⁻-semiconductor regions 12 is formed for making the source drain of the n-channel MISFET into an LDD structure.

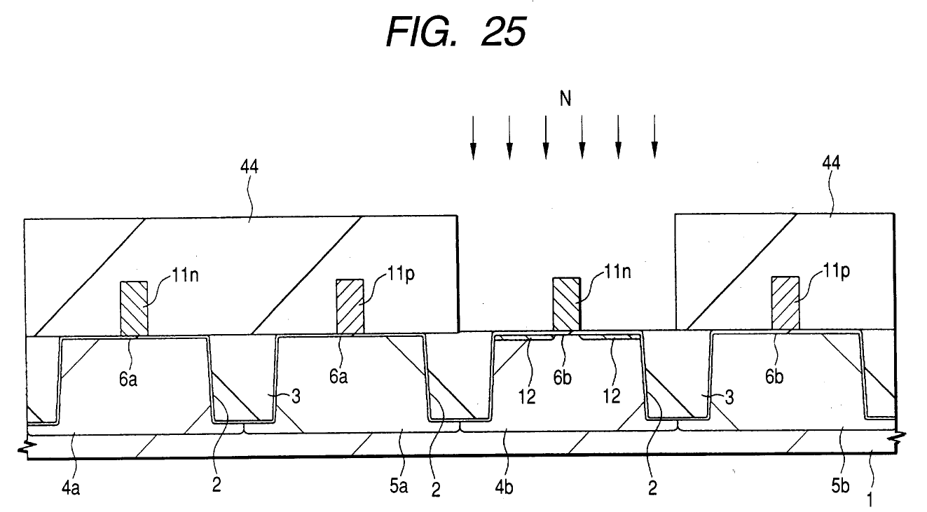

Then, as shown in FIG. 25, nitrogen is ion implanted near the boundary between the gate oxide film 6b and the p-well 4b using the photoresist film 44 as a mask. In this case, nitrogen corresponding to about 2% concentration is introduced near the boundary by controlling the dose of nitrogen, for example, to 2×10¹⁵/cm².

As described above, nitrogen of about 2.2% has been introduced by the oxynitridation processing for twice described above near the boundary between the gate oxide film 6b and the p-well 4b. Accordingly, by nitrogen ion implantation described above to the p-well 4b, the concentration of nitrogen near the boundary between the thick gate oxide film 6b and the p-well 4b in the I/O circuit region is about 4.2% which is higher than the concentration of nitrogen (about 4%) near the boundary between the thin gate oxide film 6a and the p-well 4a in the internal circuit region.

By the steps so far described above, the concentration of nitrogen introduced near the boundary between the gate oxide film and the substrate (well) is highest, at about 4.2%, for the n-channel MISFET forming region (p-well 4b) in the I/O circuit region, and successively, at about 4% for the n-channel MISFET forming region (p-well 4a) in the internal circuit region, at about 0.2% for the p-channel MISFET forming region (n-well 5b) in the I/O circuit region and at about 2% for the p-channel MISFET forming region (n-well 5a) in the internal circuit region.

In this embodiment, since nitrogen are ion implanted after forming the gate electrodes 11n, 11p, nitrogen is not introduced near the boundary between the gate oxide film 6b and the p-well 4b just below the gate electrode 11n but there are no troubles since the hot carriers can be suppressed so long as nitrogen is introduced at least near the drain region.

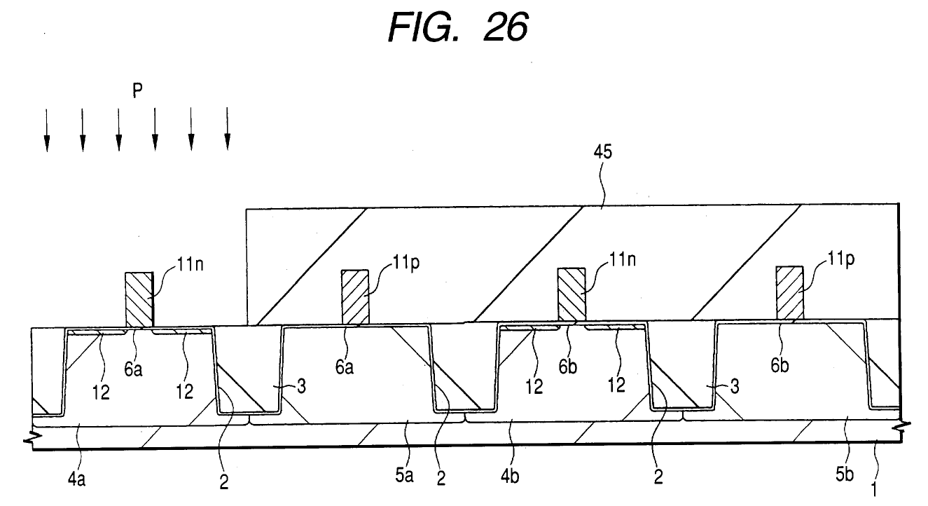

Then, after removing the photoresist film 44, as shown in FIG. 26, a photoresist film 45 opened for the portion above the p-well 4a is formed on the substrate 1, and phosphorus or arsenic is ion implanted in the p-well 4a by using the photoresist film 45 as a mask, thereby forming n⁻-semiconductor regions 12.

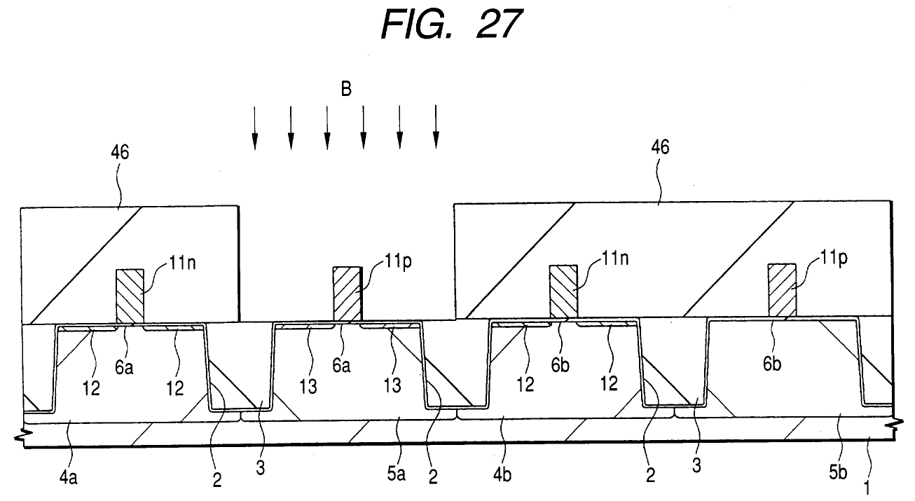

Then, after removing the photoresist film 45, as shown in FIG. 27, a photoresist film 46 opened for the a portion above the n-well 5a is formed on the substrate 1, and boron is ion implanted to the n-well 5a by using the photoresist film 46 as a mask, thereby forming p⁻-semiconductor regions 13. Successively, after removing the photoresist film 46, a photoresist film 47 opened for opening a portion above the n-well 5b is formed on the substrate 1 and boron is ion implanted to the n-well 5b by using the photoresist film 47 as a mask, thereby forming the p⁻-semiconductor regions 13. When the n⁻-semiconductor regions 12 are formed to the p-wells 4a, 4b, while the p⁻-semiconductor regions 13 are formed to the n-wells 5a, 5b by using the four types of the photoresist films 44 to 47, sequences thereof may optionally be changed.

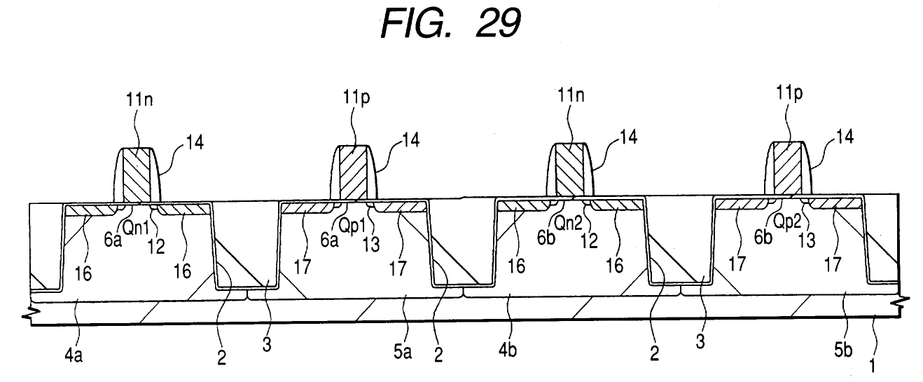

Subsequently, as shown in FIG. 29, an n-channel MISFET (Qn1) having a thin gate oxide film 6a is formed to the p-well 4a in the internal circuit region and an n-channel MISFET (Qn2) having a thick gate oxide film 6b is formed to the p-well 4b in the I/O circuit region in the same method as in Embodiment 1. Further, a p-channel MISFET (Qp1) having a thin gate oxide film 6a is formed to the n-well 5a in the internal circuit region, and a p-channel MISFET (Qp2) having a thick gate oxide film 6b is formed to the n-well 5b in the I/O circuit region. Subsequent steps are identical with those in Embodiment 1.

According to this embodiment, the concentration of nitrogen introduced near the boundary between the gate oxide film and the substrate (well) is given as: n-channel MISFET in I/O circuit region (Qn2)>n-channel MISFET in internal circuit region (Qn1)>p-channel MISFET in internal circuit region (Qp1)>p-channel MISFET in I/O circuit region (Qp2) in the order of higher concentration. Accordingly, like Embodiment 1 described above, it is possible to compatibilize the reliability to the hot carrier and the reliability to NBT by optimizing the concentration of nitrogen introduced to the boundary between the gate oxide film of four types of MISFET (Qn1, Qn2, Qp1, Qp2) of different gate oxide film thickness and the substrate (well).

Further, in this embodiment, since nitrogen is ion implanted using, as a mask, the photoresist film 44 used for forming the n⁻-semiconductor regions 12 of the n-channel MISFET (Qn2) having the thick gate oxide film 6b, another photoresist film 45 is necessary upon forming the n⁻-semiconductor regions 12 of the n-channel MISFET (Qn1) having the thin gate oxide film 6b. Accordingly, the number of the photomasks increases in a case of application to the manufacture of CMOS-LSI in which the n⁻-semiconductor regions 12 of two types of n-channel MISFET (Qn1, Qn2) are set to an identical impurities concentration. However, the number of the photomasks does not increase in a case of application to the manufacture of CMOS-LSI in which the n⁻-semiconductor regions 12 of two types of n-channel MISFET (Qn1, Qn2) are set to optimal impurity concentrations, respectively.

(Embodiment 3)

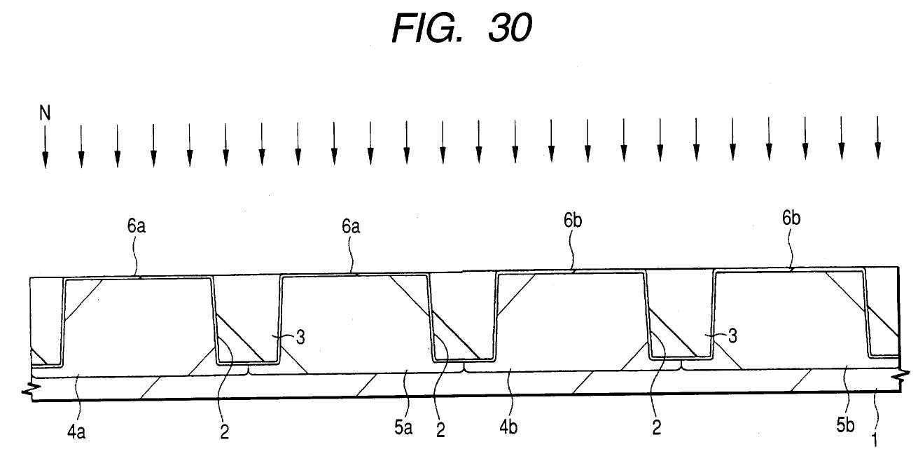

A method of manufacturing a CMOS-LSI according to this embodiment is to be described in the sequence of steps with reference to FIG. 30 to FIG. 39.

At first, as shown in FIG. 30, a thin gate oxide film 6a of about 2 nm thickness is formed to the surface of a substrate 1 in an internal circuit region (p-well 4a and n-well 5a), and a thick gate oxide film 6a of about 6 nm thickness is formed to the surface of the substrate 1 in an I/O circuit region (p-well 4b and n-well 5b). Successively, a heat treatment (oxynitridation processing) is applied to the substrate 1 in an atmosphere containing NO, thereby introducing a predetermined amount of nitrogen near the boundary between the gate oxide films 6a, 6b and the substrate 1. In this case, when the concentration of nitrogen introduced through the thin gate oxide film 6a in the internal circuit region to the substrate 1 (p-well 4a and n-well 5a) is controlled to about 2%, the concentration of nitrogen introduced through the thick gate oxide film 6b in the I/O circuit region to the substrate 1 (p-well 4b and n-well 5b) is about 0.2%. The steps so far described above are identical with the steps shown in FIG. 16 to FIG. 19 for the embodiment 2 described previously.

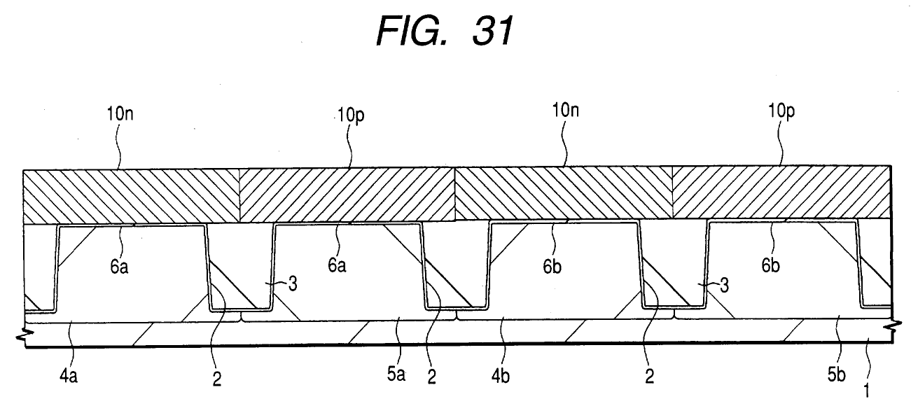

Then, as shown in FIG. 31, after depositing a non-doped polycrystal silicon film (not illustrated) on the substrate 1 by a CVD method, an n-polycrystal silicon film 10n is formed to a portion above the n-channel MISFET forming region (p-wells 4a, 4b) and a p-polycrystal silicon film 10p is formed to a portion above the p-channel MISFET forming region (n-wells 5a, 5b) by ion implantation of impurities using, as a mask, two types of photoresist films (41, 42) as described for the Embodiments 1 and 2 above.

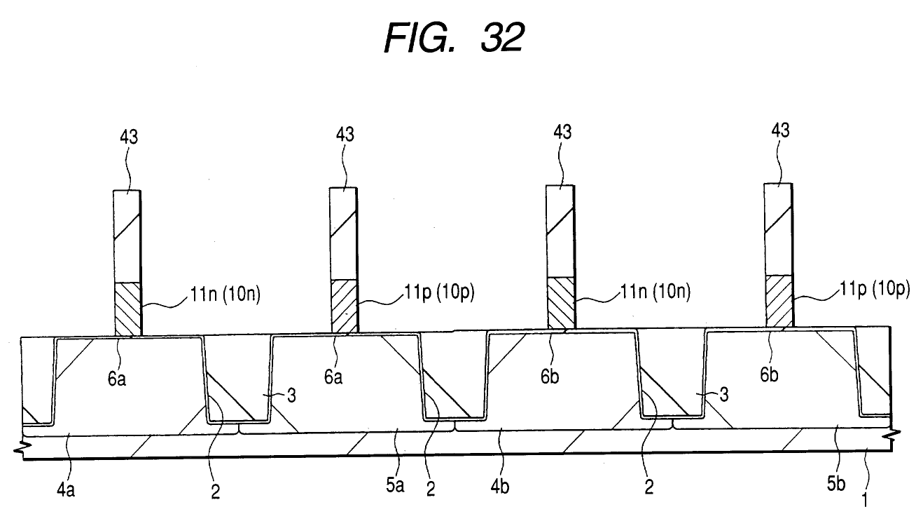

Then, as shown in FIG. 32, after removing the photoresist film the n-polycrystal silicon film 10n and the p-polycrystal silicon film 10p are dry etched by using the photoresist film 43 as a mask, thereby forming gate electrodes 11n comprising the n-polycrystal silicon film 10n above the p-wells 4a, 4b, and gate electrodes 11p comprising the p-polycrystal silicon film 10p above the n-wells 5a, 5b.

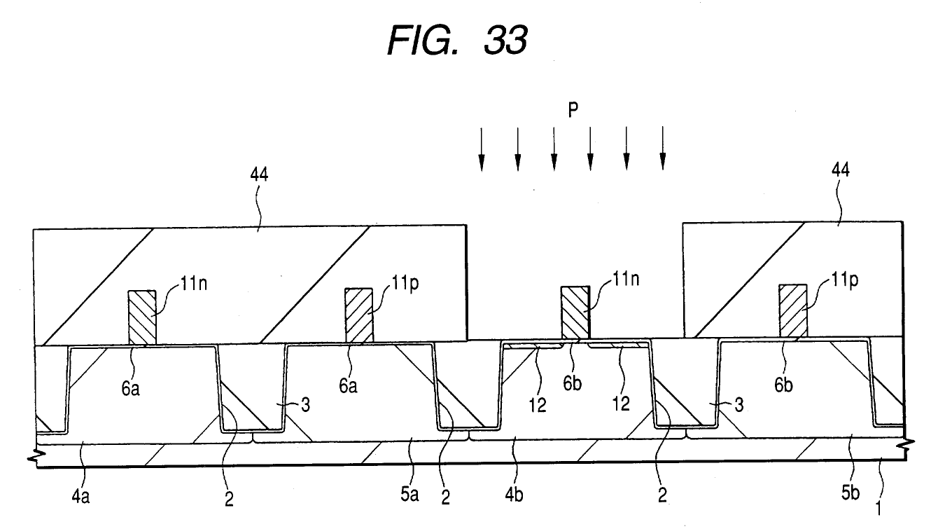

Then, as shown in FIG. 33, after removing the photoresist film 43, a photoresist film 44 opened for the portion above the p-well 4b is formed on the substrate 1, and phosphorus or arsenic is ion implanted to the p-well 4b by using the photoresist film 44 as a mask, thereby forming n⁻-semiconductor regions 12.

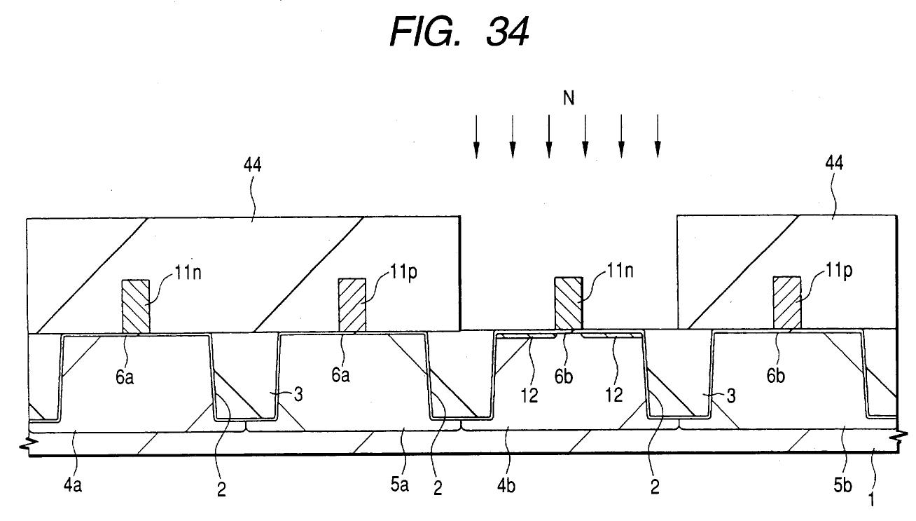

Then, as shown in FIG. 34, nitrogen is ion implanted to the p-well 4b by using the photoresist film 44 as a mask. In this step, nitrogen corresponding to the concentration at about 4% is introduced near the boundary between the gate oxide film 6b and the p-well 4b by controlling the dose of nitrogen, for example, to 4×10¹⁵/cm². As described above, nitrogen at about 0.2% has been introduced by the oxynitridation processing described above near the boundary between the gate oxide film 6b and the p-well 4b. Accordingly, the concentration of nitrogen near the boundary between the thick gate oxide film 6b in the I/O circuit region and the p-well 4b is about 4.2% by the ion implantation of nitrogen to the p-well 4b.

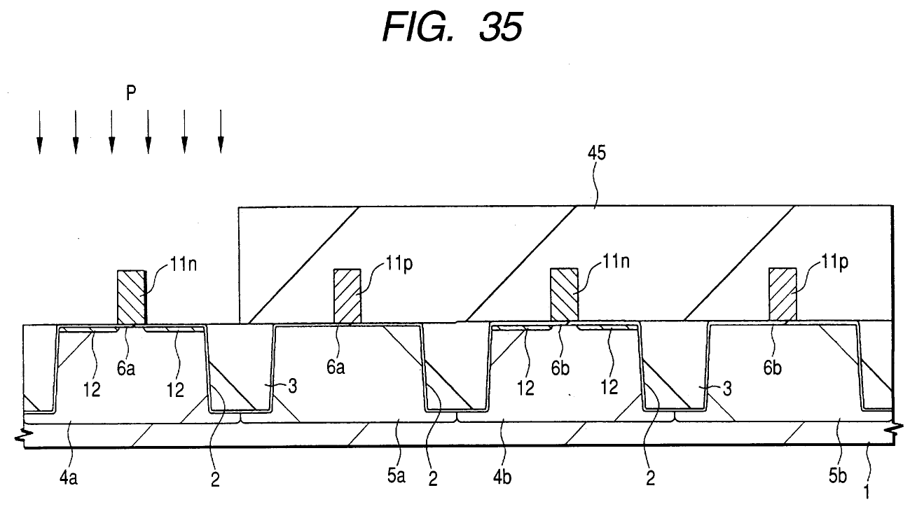

Then, after removing the photoresist film 44, as shown in FIG. 35, a photoresist film 45 opened for the portion above the p-well 4a is formed on the substrate 1, and phosphorus or arsenic is ion implanted in the p-well 4a using the photoresist film 45 as a mask, thereby forming n⁻-semiconductor regions 12.

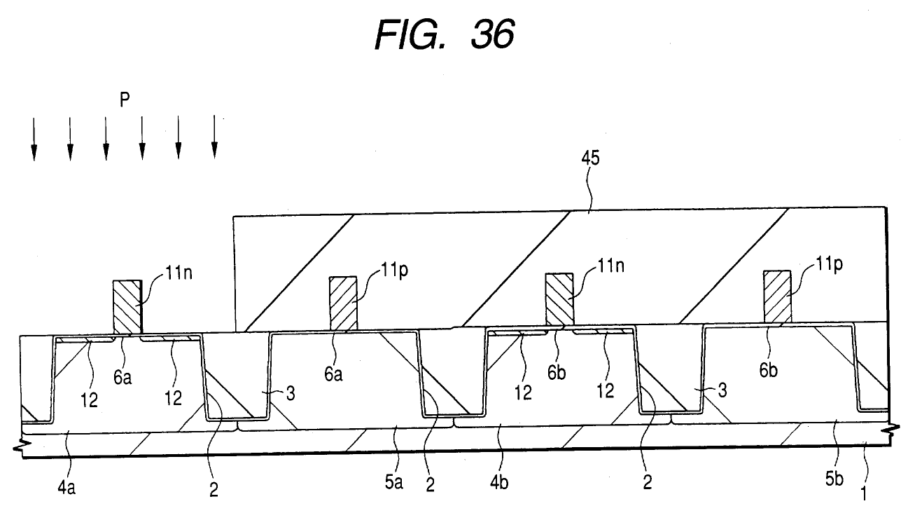

Then, as shown in FIG. 36, nitrogen is ion implanted near the boundary between the gate oxide film 6a and the p-well 4a by using the photoresist film 45 as a mask. In this case, nitrogen corresponding to about 2% concentration is introduced near the boundary by controlling the dose of nitrogen, for example, to 2×10¹⁵/cm². As described above, nitrogen of about 2% has been introduced by the oxynitridation for twice processing described above near the boundary between the gate oxide film 6a and the p-well 4a. Accordingly, by nitrogen ion implantation described above to the p-well 4a, the concentration of nitrogen near the boundary between the thin gate oxide film 6a in the internal circuit region and the p-well 4a is about 4%.

By the steps so far described above, the concentration of nitrogen introduced near the boundary between the gate oxide film and the substrate (well) is highest at about 4.2% for the n-channel MISFET forming region (p-well 4b) in the I/O circuit region, successively, at about 4% for the n-channel MISFET forming region (p-well 4a) in the internal circuit region, at about 2% for the p-channel MISFET forming region (n-well 5a) in the internal circuit region and at about 0.2% for the p-channel MISFET forming region (n-well 5b) in the I/O circuit region.

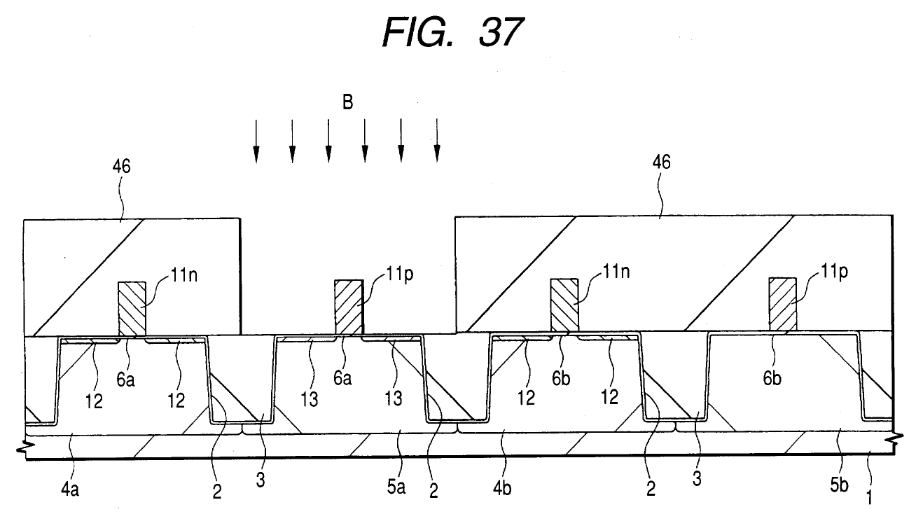

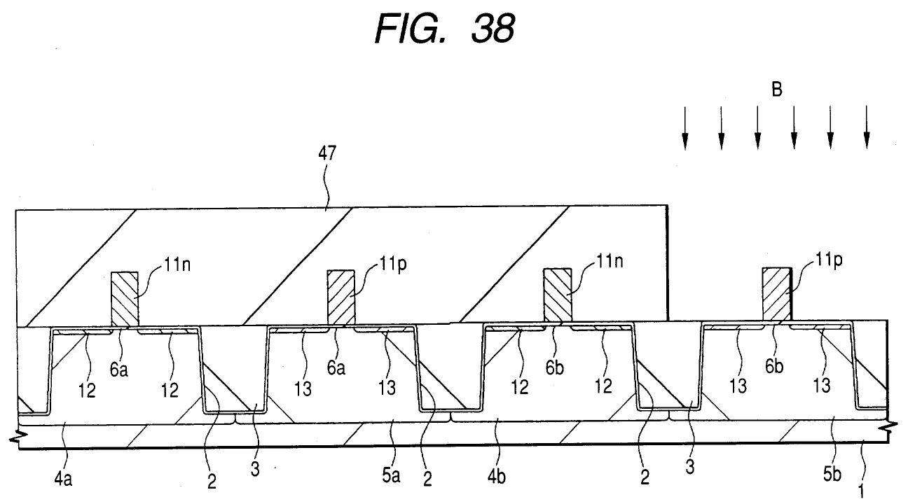

Then, after removing the photoresist film 45, as shown in FIG. 37, a photoresist film 46 opened for the portion above the n-well 5a is formed on the substrate 1, and boron is ion implanted in the n-well 5a by using the photoresist film 46 as a mask, thereby forming p⁻-semiconductor regions 13. Successively, after removing the photoresist film 46, as shown in FIG. 38, a photoresist film 47 opened for the portion above the n-well 5b is formed on the substrate 1, boron is ion implanted to the n-well 5b by using the photoresist film 47 as a mask, thereby forming p⁻-semiconductor regions 13. When n-type impurities or nitrogen are ion implanted to the p-wells 4a, 4b or p-type impurities are ion implanted to n-wells 5a, 5b by using four types of the photoresist films 44 to 47 described above, their sequence may optionally be changed.

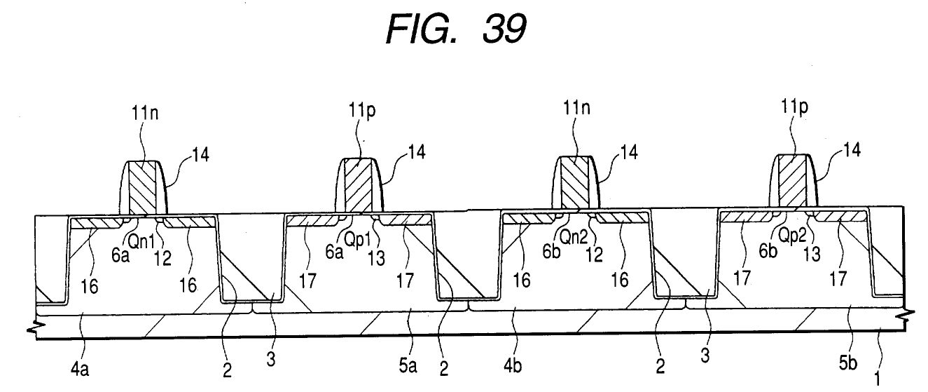

Subsequently, as shown in FIG. 39, an n-channel MISFET (Qn1) having a thin gate oxide film 6a is formed to the p-well 4a in the internal circuit region and an n-channel MISFET (Qn2) having a thick gate oxide film 6b is formed to the p-well 4b in the I/O circuit region in the same method as in Embodiments 1 and 2. Further, a p-channel MISFET (Qp1) having a thin gate oxide film 6a is formed to the n-well 5a in the internal circuit region, and a p-channel MISFET (Qp2) having a thick gate oxide film 6b is formed to the n-well 5b in the I/O circuit region.

According to this embodiment, the concentration of nitrogen introduced near the boundary between the gate oxide film and the substrate (well) is given as: n-channel MISFET in I/O circuit region (Qn2)>n-channel MISFET in internal circuit region (Qn1)>p-channel MISFET in internal circuit region (Qp1)>p-channel MISFET in I/O circuit region (Qp2) in the order of higher concentration. Accordingly, like Embodiments 1 and 2 described above, it is possible to compatibilize the reliability to the hot carriers and the reliability to NBT by optimizing the concentration of nitrogen introduced to the boundary between the gate oxide film of four types of MISFET (Qn1, Qn2, Qp1, Qp2) of different gate oxide film thickness and the substrate (well).

Since the concentration of nitrogen introduced near the boundary between the thick gate oxide film 6b and the n-well 5b of the n-channel MISFET (Qn2) may be identical with or higher than the concentration of nitrogen introduced near the boundary between the thin gate oxide film 6a and the n-well 5a of the n-channel MISFET (Qn1), the nitrogen concentration in both of them may be identical. In the manufacturing method according to this embodiment, the nitrogen concentration in the n-channel MISFET (Qn1) and the nitrogen concentration in the n-channel MISFET (Qn2) can be made identical by making the value of the nitrogen dose different in the nitrogen ion implantation step shown in FIG. 34 and in the nitrogen ion implantation step shown in FIG. 36.

(Embodiment 4)

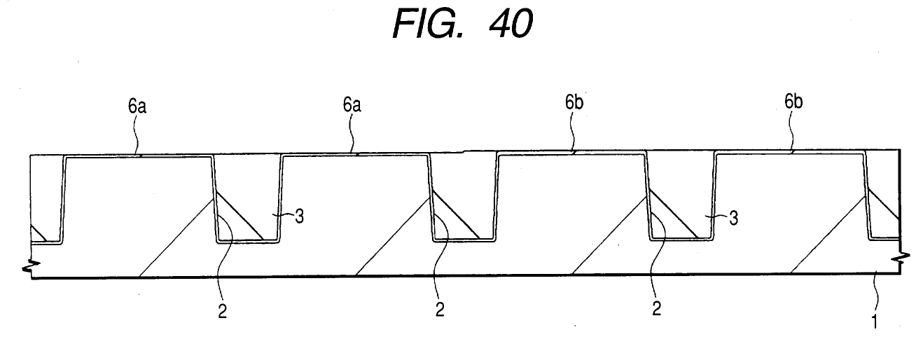

A method of manufacturing a CMOS-LSI according to this embodiment is to be described in the sequence of steps with reference to FIG. 40 to FIG. 46.

At first, as shown in FIG. 40, a thin gage oxide film 6a of about 2 nm thickness is formed to the surface of a substrate 1 in an internal circuit region and a thick gate oxide film of about 6 nm thickness is formed to the surface of the substrate 1 in an I/O circuit region. The two types of the gate oxide films 6a, 6b of different film thickness are formed in the same method as in Embodiments 1 to 3 described above. In this embodiment, the gate oxide films 6a, 6b are formed before the step of forming the p-wells 4a, 4b and the n-wells 5a, 5b to the substrate 1.

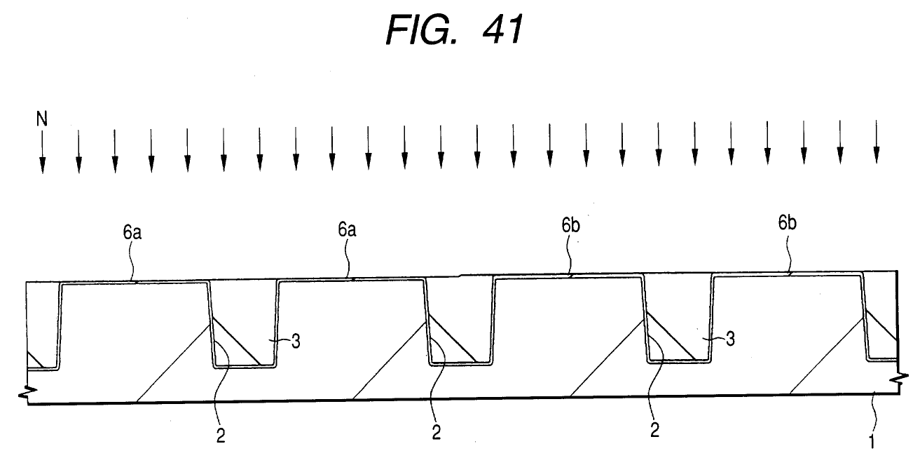

Then, as shown in FIG. 41, nitrogen of about 2% is introduced through the thin gage oxide film 6a in the internal circuit region near the boundary between the gate oxide film 6a and the substrate 1. In this case, concentration of nitrogen introduced near the boundary between the thick gate oxide film 6b in the I/O circuit region and the substrate 1 is about 0.2%.

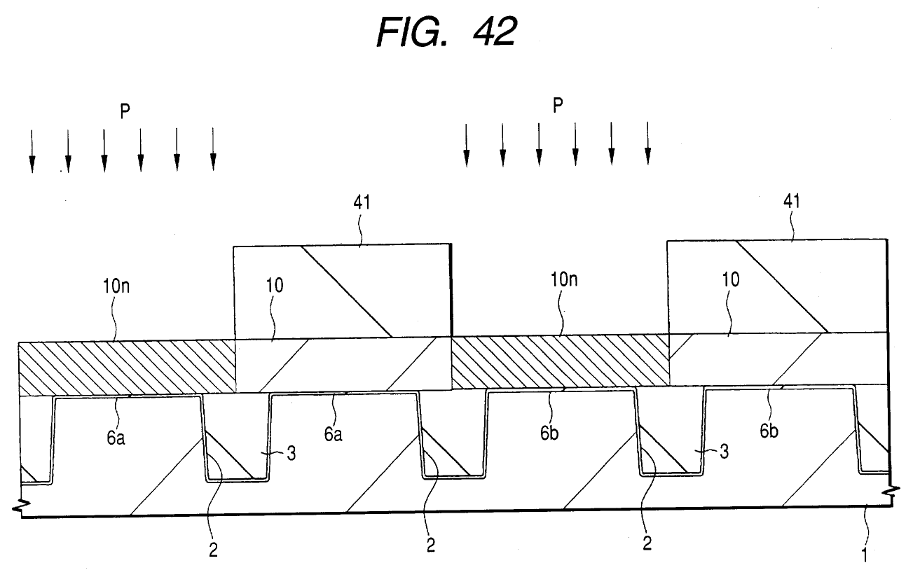

Then, as shown in FIG. 42, after depositing a non-doped polycrystal silicon film 10 on the substrate 1 by a CVD method, the polycrystal silicon film 10 above the p-channel MISFET forming region is covered with a photoresist film 41 and phosphorus or arsenic is ion implanted to the polycrystal silicon film 10 above the n-channel MISFET forming region, thereby converting the polycrystal silicon film 10 in this region into an n-polycrystal silicon film 10n of low resistivity.

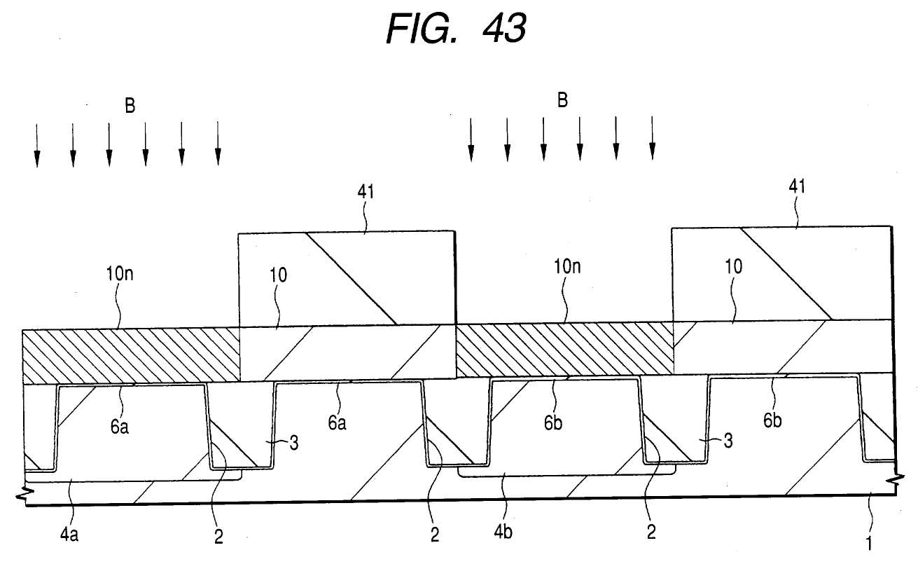

Then, as shown in FIG. 43, boron is ion implanted to the substrate 1 in the n-channel MISFET forming region through the n-polycrystal silicon film 10n while leaving the photoresist film 41 in the p-channel MISFET forming region, thereby forming p-wells 4a, 4b to the substrate in the region. In this case, boron is ion implanted also to the surface of the p-wells 4a, 4b (channel forming region) in order to control the threshold voltage of the n-channel MISFET. The ion implantation is applied in order to optimize the threshold voltage of the n-channel MISFET (Qn1) formed on the p-well 4a.

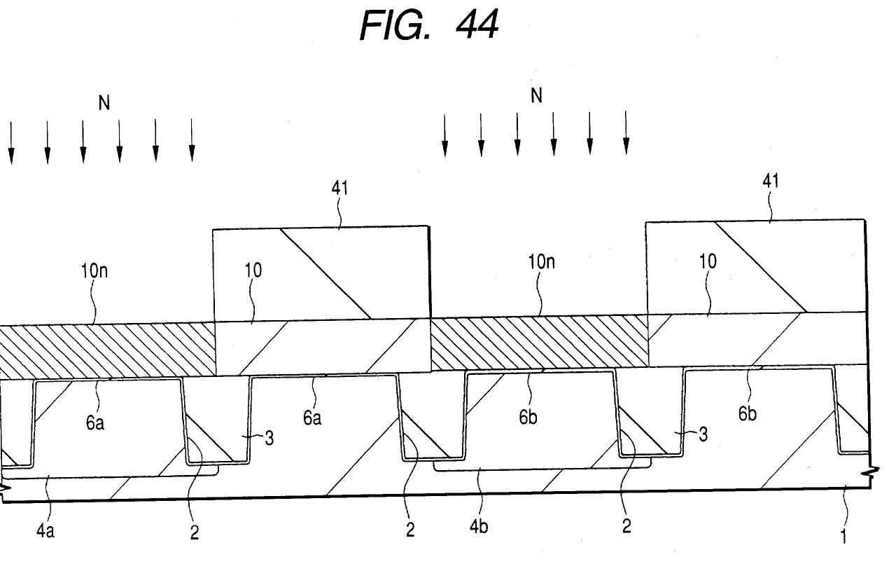

Then, as shown in FIG. 44, nitrogen is ion implanted near the boundary between the gate oxide film 6a and the p-well 4a and near the boundary between the gate oxide film 6b and the p-well 4b while leaving the photoresist film 41 in the p-channel MISFET forming region. In this case, nitrogen corresponding to the concentration of about 2% is introduced near the boundary controlling the dose of nitrogen, for example, to 5×10¹⁴/cm².

As described above, nitrogen of about 2% has been introduced by the oxynitridation processing near the boundary between the thin gate oxide film 6a in the internal circuit region and the p-well 4a. Accordingly, the concentration of nitrogen near the boundary between the gate oxide film 6a and the P-well 4a is about 4% by the ion implantation of nitrogen described above. Further, nitrogen of about 0.2% is introduced by the oxynitridation processing described above near the boundary between the thick gate oxide film 6b and the p-well 4b in the I/O circuit region. Accordingly, the concentration of nitrogen near the boundary between the gate oxide film 6b and the p-well 4b is about 2.2%.

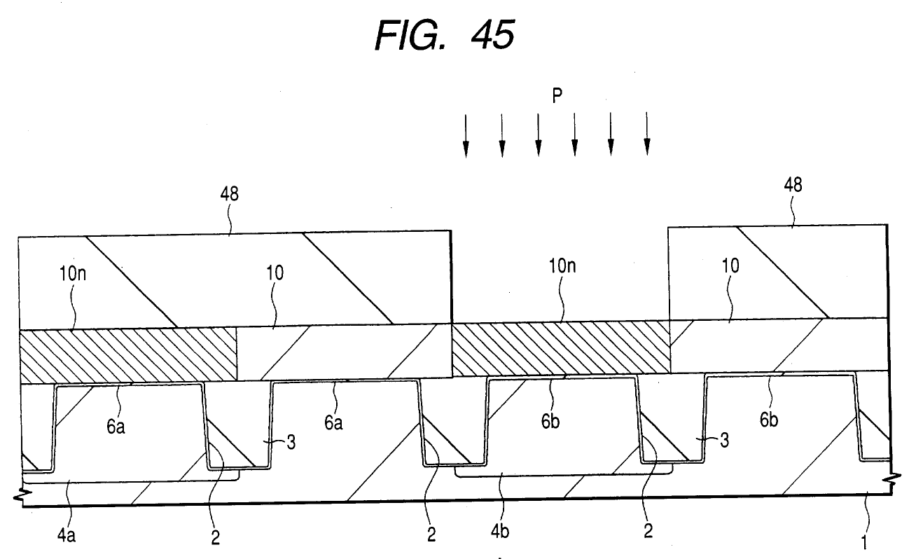

Then, after removing the photoresist film 41, as shown in FIG. 45, a photoresist film 48 opened for the portion above the p-well 4b is formed on the polycrystal silicon film 10 and the n-polycrystal silicon film 10n, and phosphorus ion is ion implanted to the surface of the p-well 4b (channel forming region) by using the photoresist film 48 as a mask. Thus, concentration of the channel impurity (boron) in the n-channel MISFET (Qn2) having the thick gate oxide film 6b is lower than the concentration of the channel impurity (boron) in the n-channel MISFET (Qn1) having the thin gate oxide film 6, thereby optimizing the threshold voltage thereof.

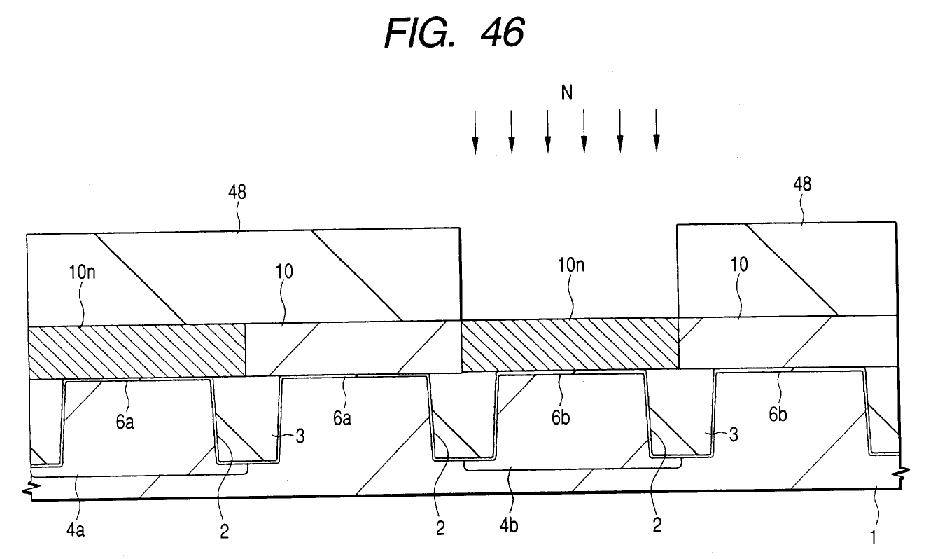

Then, as shown in FIG. 46, nitrogen is ion implanted near the boundary between the gate oxide film 6b and the p-well 4b by using the photoresist film 48 as a mask. In this case, nitrogen corresponding to the concentration of about 2% is introduced near the boundary by controlling the dose of nitrogen, for example, to 5×10¹⁴/cm².

As described above, nitrogen of about 2.2% has been introduced by the oxynitridation processing and the nitrogen ion implantation described above near the boundary between the gate oxide film 6b and the p-well 4b. Accordingly, when second nitrogen ion implantation is applied by using the photoresist film 48 as described above as a mask to the p-well 4b, the concentration of nitrogen near the boundary between the thick gate oxide film 6b and the p-well 4b in the I/O circuit region is about 4.2% which is higher than the concentration of nitrogen (about 4%) near the boundary between the thin gate oxide film 6a and the p-well 4a in the I/O circuit region.

By the steps so far described above, the concentration of nitrogen introduced near the boundary between the gate oxide film and the substrate (well) is highest at about 4.2% for the n-channel MISFET forming region (p-well 4b) in the I/O circuit region, successively, at about 4% for the n-channel MISFET forming region (p-well 4a) in the internal circuit region, at about 2% for the p-channel MISFET forming region in the I/O circuit region and at about 0.2% for the p-channel MISFET forming region in the internal circuit region.

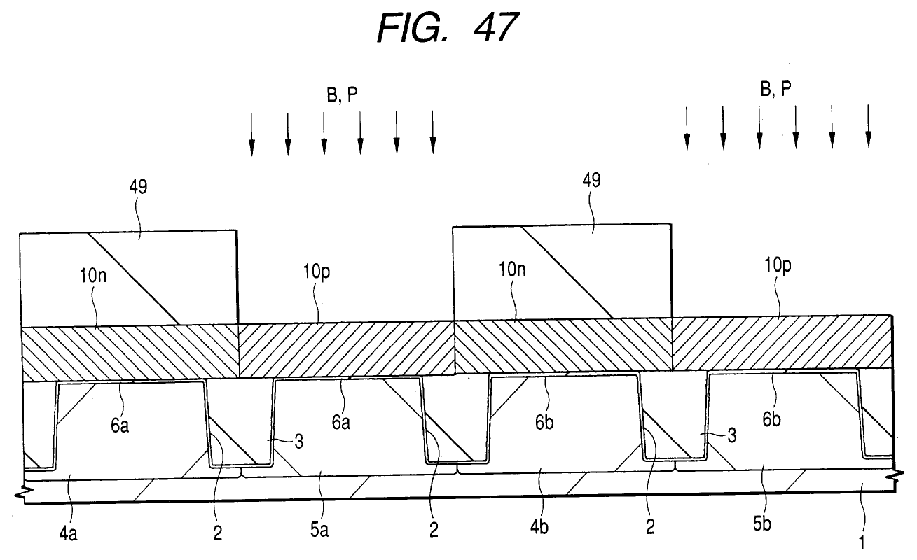

Then, after removing the photoresist film 48, as shown in FIG. 47, the n-polycrystal silicon film 10n above the n-channel MISFET forming region (p-wells 4a, 4b) is covered with a photoresist film 49 and boron is implanted to the polycrystal silicon film 10 above the p-channel MISFET forming region, thereby converting the polycrystal silicon film 10 in the region into a p-polycrystal silicon film 10p of low resistivity. Successively, phosphorus is ion implanted through the p-polycrystal silicon film 10p to the substrate 1 in the p-channel MISFET forming region while leaving the photoresist film 49 in the n-channel MISFET forming region (p-wells 4a, 4b), thereby forming n-wells 5a, 5b to the substrate 1 in the region. Further, in this case, phosphorus ion is ion implanted also to the surface of the n-wells 5a, 5b (channel forming region) in order to control the threshold voltage of the p-channel MISFET. The ion implantation is applied for optimizing the threshold voltage of the p-channel MISFET (Qp1) formed to the n-well 5a.

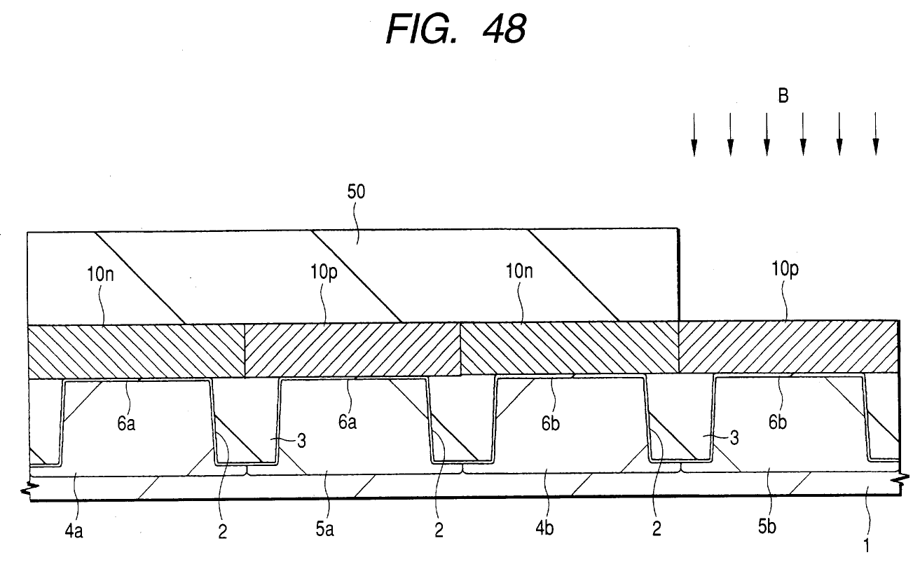

Then, after removing the photoresist film 49, as shown in FIG. 48, a photoresist film 50 opened for the portion above the n-well 5b is formed on the p-polycrystal silicon film 10p and the n-polycrystal silicon film 10n, and boron is ion implanted to the surface of the n-well 5b (channel forming region) by using the photoresist film 50 as a mask. Thus, the concentration of the channel impurity (phosphorus) in the p-channel MISFET (Qp2) having the thick gate oxide film 6b is lower than the concentration of the channel impurity (phosphorus) in the p-channel MISFET (Qp1) having the thin gate oxide film 6, thereby optimizing the threshold voltage thereof.

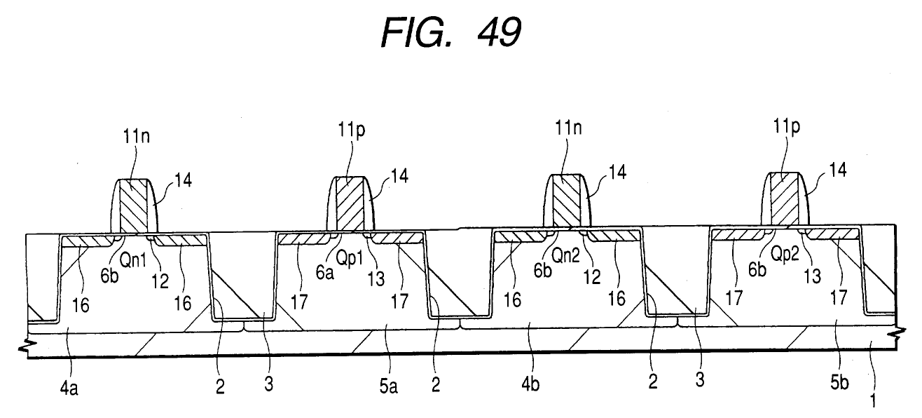

Then, as shown in FIG. 49, in accordance with the steps shown in FIG. 12 to FIG. 14 of Embodiment 1, an n-channel MISFET (Qn1) having a thin gate oxide film 6a is formed to the p-well 4a in the internal circuit region, and an n-channel MISFET (Qn2) having a thick gate oxide film 6b is formed to the p-well 4b in the I/O circuit region. Further, a p-channel MISFET (Qp1) having a thin gate oxide film 6a is formed to the n-well 5a in the internal circuit region, and a p-channel MISFET (Qp2) having a thick gate oxide film 6b is formed to the n-well 5b in the I/O circuit region.

Also in this embodiment, the concentration of nitrogen introduced is given as: n-channel MISFET in I/O circuit region (Qn2)>n-channel MISFET in internal circuit region (Qn1)>p-channel MISFET in internal circuit region (Qp1)>p-channel MISFET in I/O circuit region (Qp2), in the order of higher concentration. In the manufacturing method according to this embodiment, the nitrogen concentration in the n-channel MISFET (Qn1) may be identical with the nitrogen concentration in the n-channel MISFET (Qn2) by making the dose of nitrogen in the nitrogen ion implantation step shown in FIG. 46 different from the value described above.

According to this embodiment, it is possible to compatibilize the reliability to the hot carrier and the reliability to the NBT by optimizing the concentration of nitrogen introduced to the boundary between the gate oxide film of four types of MISFET of different conduction type and different gate oxide film thickness (Qn1, Qn2, Qp1, Qp2) and the substrate (well). Further, according to this embodiment, since there is no requirement of adding the photomask upon introduction of nitrogen, the foregoing effect can be obtained while minimizing increase in the manufacturing the cost.

The inventions made by the present inventors have been described specifically with reference to the embodiments of the invention but the invention is not restricted to the embodiments but may be changed variously within a range not departing from the gist thereof.

For example, concentration of nitrogen shown in Embodiments 1 to 4 is not restricted only thereto. Further, it is also possible to optimize the concentration of nitrogen to be introduced to the boundary between the gate oxide films of four types of MISFET (Qn1, Qn2, Qp1, Qp2) of different conduction type and different gate oxide film thickness and the substrate (well) by properly combining the methods explained in Embodiments 1 to 4.

The effects obtained by typical inventions among those disclosed in the present application are to be explained simply as below.

Reliability to hot carriers and reliability to NBT can be optimized without increasing the number of photomasks in a semiconductor integrated circuit device in which MISFET having a thin gate insulative film and MISFET having a thick gate insulative film are present together.

What is claimed is:

1. A method of manufacturing a semiconductor integrated circuit device comprising the following steps of:
(a) forming a first insulative film to the surface of each of a first p-well, a second p-well, a first n-well and a second n-well formed to a main surface of a semiconductor substrate and then applying a heat treatment to the semiconductor substrate in an atmosphere containing nitrogen, thereby forming a first nitridation region having a first nitrogen concentration to the boundary between each of the wells and the first insulative film,
(b) removing the first insulative film and the first nitridation region formed to the first p-well, and the first insulative film and the first nitridation region formed in the first n-well, respectively, and leaving the first insulative film and the first nitridation region to the second p-well and the second n-well, respectively,
(c) applying thermal oxidation to the semiconductor substrate, thereby forming a first gate insulative film to the surface of each of the first p-well and the first n-well, and forming a second gate insulative film including the first insulative film as a portion thereof and having a thickness larger than that of the first gate insulative film,
(d) applying a heat treatment to the semiconductor substrate in an atmosphere containing nitrogen, thereby forming a second nitridation region having a second nitrogen concentration to the boundary between the first p-well and the first gate insulative film and to the boundary between the first n-well and the first gate insulative film, and forming a third nitridation region containing nitrogen in the first nitridation region as a portion thereof and having a third nitrogen concentration higher than the second nitrogen concentration to the boundary between the second p-well and the second gate insulative film and the boundary between the second n-well and the second gate insulative film,
(e) depositing a silicon film on the semiconductor substrate, then forming a first photoresist film on each of the first n-well and the second n-well, and forming an n-silicon film by ion implanting n-impurities to the silicon film on each of the first p-well and the second p-well,
(f) ion implanting nitrogen through the n-silicon film to each of the first p-well and the second p-well, while leaving the first photoresist film above each of the first n-well and the second n-well, thereby
forming a fourth nitridation region containing nitrogen in the second nitridation region as a portion thereof and having a fourth nitrogen concentration higher than the third nitrogen concentration to the boundary between the first p-well and the first gate insulative film, and
forming a fifth nitridation region containing nitrogen of the third nitridation region as a portion thereof and having a fifth nitrogen concentration higher than the fourth nitrogen concentration to the boundary between the second p-well and the second gate insulative film,
(g) forming a second photoresist film above each of the first p-well and the second p-well, and ion implanting p-impurities to the silicon film above each of the first n-well and the second n-well, thereby converting the same into a p-type silicon film,
(h) patterning each of the n-silicon film and the p-silicon film, thereby forming a n-semiconductor piece comprising the n-silicon film above each of the first p-well and the second p-well and forming a p-semiconductor piece comprising the p-silicon film above each of the first n-well and the second n-well,
(i) forming source and drain comprising an n-semiconductor region to each of the first p-well and the second p-well and forming source and drain comprising a p-semiconductor region to each of the first n-well and the second well after the step (h) described above, thereby
forming a first p-channel MISFET having source and drain comprising the p-semiconductor region, the first gate insulative film, a gate electrode containing the p-semiconductor piece and the second nitridation region in the first n-well,
forming a second p-channel MISFET having source and drain comprising the p-semiconductor region, the second insulative film, a gate electrode containing the p-semiconductor piece and the third nitridation region in the second n-well,
forming a first n-channel MISFET having source and drain comprising the n-semiconductor region, the first insulative film, a gate electrode containing the n-semiconductor piece and the fourth nitridation region in the first p-well, and
forming a second n-channel MISFET having source and drain comprising the n-semiconductor region, the second insulative film, a gate electrode containing the n-semiconductor piece and the fifth nitridation region in the second p-well.

2. A method of manufacturing a semiconductor integrated circuit device according to claim 1, wherein the step of forming the n-silicon film above each of the first p-well and the second p-well in the step (e) is conducted after the step (f).

3. A method of manufacturing a semiconductor integrated circuit device comprising the following steps of:
(a) forming a first p-well, a second p-well, a first n-well and a second n-well to a main surface of a semiconductor substrate, then forming a first gate insulative film to the surface for each of the first p-well and the n-well, respectively, and forming a second gate insulative film having a thickness larger than that of the first gate insulative film to the surface for each of the second p-well and the second n-well,
(b) applying a heat treatment to the semiconductor substrate in an atmosphere containing nitrogen, thereby forming a first nitridation region having a first nitrogen concentration to the boundary between the second p-well and the second gate insulative film and to the boundary between the second n-well and the second gate insulative film, and forming a second nitridation region having a second nitrogen concentration higher than the first nitrogen concentration to the boundary between the first p-well and the first gate insulative film and to the boundary between the first n-well and the first gate insulative film,
(c) depositing a silicon film on the semiconductor substrate, then forming a first photoresist film above each of the first n-well and the second n-well, then ion implanting n-impurities to the silicon film above each of the first p-well, and the second p-well thereby forming a n-silicon film,
(d) ion implanting nitrogen through the n-silicon film to the first p-well and the second p-well while leaving the first photoresist above each of the first n-well and the second n-well, thereby
forming a third nitridation region containing nitrogen in the first nitridation region as a portion thereof and having a third nitrogen concentration higher than the second nitrogen concentration to the boundary between the second p-well and the second gate insulative film, and
forming a fourth nitridation region containing nitrogen in the second nitridation region as a portion thereof and having a fourth nitrogen concentration higher than the third nitrogen concentration to the boundary between the first p-well and the first gate insulative film,
(e) forming a second photoresist film above each of the first p-well and the second p-well and forming a p-silicon film by ion implanting p-impurities to the silicon film above each of the first n-well and the second n-well,
(f) patterning each of the n-silicon film and p-silicon film, thereby forming an n-semiconductor piece comprising the n-silicon film above each of the first p-well and the second p-well, and forming a p-semiconductor piece comprising the p-silicon film above each of the first n-well and the second n-well,
(g) forming a third photoresist film above each of the first p-well, the first n-well and the second n-well, after the step (f) above, and ion implanting n-impurities to the second p-well, thereby forming an n-semiconductor region constituting a portion of source and drain in the second p-well,
(h) ion implanting nitrogen in the second p-well while leaving the third photoresist film above each of the first p-well, first n-well and the second n-well, thereby forming a fifth nitridation region containing nitrogen in the third nitridation region as a portion thereof and having a fifth nitrogen concentration higher than the fourth nitrogen concentration to the boundary between the second p-well and the second gate insulative film, and
(i) forming source and drain comprising the n-semiconductor region to each of the first p-well and the second p-well, after the step (h) and forming source and drain comprising a p-semiconductor region to each of the first n-well and the second n-well, after the step (h) above, thereby
forming a first p-channel MISFET having source and drain comprising the p-semiconductor region, the first gate insulative film, a gate electrode containing the p-semiconductor piece and the second nitridation region in the first n-well,
forming a second p-channel MISFET having source and drain comprising the p-semiconductor region, the second gate insulative film, a gate electrode containing the p-semiconductor piece and the first nitridation region in the second n-well,
forming a first n-channel MISFET having source and drain comprising the n-semiconductor region, the first gate insulative film, a gate electrode containing the n-semiconductor piece and a fourth nitridation region in the first p-well, and
forming a second n-channel MISFET having source and drain comprising the n-semiconductor region, the second gate insulative film, a gate electrode containing the n-semiconductor piece and a fifth nitridation region in the second p-well.

4. A method of manufacturing a semiconductor integrated circuit device according to claim 3, wherein the step of forming the n-silicon film above each of the first p-well and the second p-well in the step (c) is conducted after the step (d).

5. A method of manufacturing a semiconductor integrated circuit device according to claim 3, wherein the step of forming the n-semiconductor region in the second p-well in the step (g) is conducted after the step (h).

6. A method of manufacturing a semiconductor integrated circuit device comprising the following steps of:
(a) forming a first p-well, a second p-well, a first n-well and a second n-well to a main surface of a semiconductor substrate, then forming a first gate insulative film to the surface for each of the first p-well and the first n-well, and forming a second gate insulative film having a thickness larger than that of the first gate insulative film to the surface for each of the second p-well and the second n-well,
(b) applying a heat treatment to the semiconductor substrate in an atmosphere containing nitrogen, thereby forming a first nitridation region having a first nitrogen concentration to the boundary between the second p-well and the second gate insulative film and to the boundary between the second n-well and the second gate insulative film, and forming a second nitridation region having a second nitrogen concentration higher than the first nitrogen concentration to the boundary between the first p-well and the first gate insulative film and to the boundary between the first n-well and the first gate insulative film,
(c) forming an n-silicon film above each of the first p-well and the second p-well, and forming a p-silicon film above each of the first n-well and the second n-well,
(d) patterning each of the n-silicon film and the p-silicon film, thereby forming an n-semiconductor piece comprising the n-silicon film above each of the first p-well and the second p-well, and forming a p-semiconductor piece comprising the p-silicon film above each of the first n-well and the second n-well,
(e) forming a first photoresist film above each of the first p-well, the first n-well and the second n-well after the step
(d) above, and ion implanting n-impurities in the second p-well, thereby constituting a portion of source and drain,
(f) ion implanting nitrogen in the second p-well while leaving the first photoresist film above each of the first p-well, the first n-well and the second n-well respectively, thereby forming a third nitridation region containing nitrogen in the first nitridation region as a portion thereof and having a third nitrogen concentration higher than the second nitrogen concentration to the boundary between the second p-well and the second gate insulative film,
(g) forming a second photoresist film above each of the second p-well, the first n-well, the second n-well, and ion implanting n-impurities in the first p-well thereby constituting a portion of source and drain,
(h) ion implanting nitrogen in the first p-well while leaving the second photoresist film above each of the second p-well, the first n-well and the second n-well, thereby forming a fourth nitridation region containing nitrogen in the second nitridation region as a portion thereof and having a fourth nitrogen concentration higher than the second nitrogen concentration and equal with or lower than the third nitridation concentration,
(i) forming source and drain comprising an n-semiconductor region to each of the first p-well and the second p-well and forming source and drain comprising a p-semiconductor region to each of the first n-well and the second n-well after the step (h), thereby
forming a first p-channel MISFET having source and drain comprising the p-semiconductor region, the first gate insulative film, a gate electrode containing the p-semiconductor piece and a second nitridation region in the first n-well,
forming a second p-channel MISFET having source and drain comprising the p-semiconductor region, the second gate insulative film, a gate electrode including the p-semiconductor piece and the first nitridation region in the second n-well,
forming a first n-channel MISFET having source and drain comprising the n-semiconductor region, the first gate insulative film, a gate electrode including the n-semiconductor piece and the fourth nitridation region in the first p-well, and
forming a second n-channel MISFET having source and drain comprising the n-semiconductor region, the second gate insulative film, a gate electrode including the n-semiconductor piece and the third nitridation region in the second p-well.

7. A method of manufacturing a semiconductor integrated circuit device according to claim 6, wherein ion implantation of nitrogen in the step (f) is conducted before ion implantation of the n-impurities in the step (e).

8. A method of manufacturing a semiconductor integrated circuit device according to claim 6, wherein ion implantation of nitrogen in the step (h) is conducted before ion implantation of the n-impurities in the step (g).

9. A method of manufacturing a semiconductor integrated circuit device comprising the following steps of:
(a) forming a first gate insulative film to a first region and a second region on a main surface of a semiconductor substrate and forming a second gate insulative film having a thickness larger than the first gate insulative film to a third region and a fourth region on the main surface of the semiconductor substrate,
(b) applying a heat treatment to the semiconductor substrate in an atmosphere containing nitrogen, thereby forming a first nitridation region having a first nitrogen concentration to the boundary between the semiconductor substrate and the second gate insulative film in the third region and to the boundary between the semiconductor substrate and the second gate insulative film in the fourth region, and forming a second nitridation region having a second nitrogen concentration higher than the first nitrogen concentration to the boundary between the semiconductor substrate and the first gate insulative film in the first region and to the boundary between the semiconductor substrate and the first gate insulative film in the second region,
(c) depositing a silicon film on the semiconductor substrate, then forming a first photoresist film on the silicon film in the second region and the fourth region and forming an n-silicon film by ion implanting n-impurities to the silicon film in the first region and the third region,
(d) ion implanting p-impurities through the n-silicon film to the semiconductor substrate while leaving the first photoresist film on the silicon film in the second region and the fourth region, thereby forming a first p-well in the first region and forming a second p-well in the third region of the semiconductor substrate,
(e) ion implanting nitrogen through the n-silicon film to each of the first p-well and the second p-well while leaving the first photoresist film on the silicon film in the second region and the fourth region, thereby
forming a third nitridation region containing nitrogen in the first nitridation region as a portion thereof to the boundary between the second p-well and the second gate insulative film and
forming a fourth nitridation region containing nitrogen in the second nitridation region as a portion thereof and having a fourth nitrogen concentration higher than the second nitrogen concentration to the boundary between the first p-well and the first gate insulative film,
(f) forming a second photoresist film above each of the silicon film in the second region and the fourth region and the n-silicon film in the first region, and ion implanting n-impurities through the n-silicon film in the second p-well, thereby optimizing the threshold voltage of an n-channel MISFET formed in the second p-well,
(g) ion implanting nitrogen through the n-silicon film in the second p-well while leaving the second photoresist film above each of the silicon film in the second region and the fourth region and the n-silicon film in the first region, thereby forming a fifth nitridation region containing nitrogen in the third nitridation region as a portion thereof and having a fifth nitrogen concentration equal with or higher than the fourth nitrogen concentration to the boundary between the second p-well and the second gate insulative film,
(h) forming a third photoresist film on the n-silicon film and ion implanting p-impurities to the silicon film in the second region and the fourth region, thereby forming a p-silicon film,
(i) ion implanting n-impurities through the p-silicon film into the semiconductor substrate while leaving the third photoresist film on the n-silicon film, thereby forming a first n-well in the second region and forming a second n-well in the fourth region of the semiconductor substrate,
(j) patterning the n-silicon film and the p-silicon film, respectively, thereby forming an n-semiconductor piece comprising the n-silicon film above each of the first p-well and the second p-well, and forming a p-semiconductor piece comprising the p-silicon film above each of the first n-well and the second n-well, and
(k) forming source and drain comprising an n-semiconductor region to the first p-well and the second p-well, respectively, and forming source and drain comprising a p-semiconductor region to the first n-well and the second n-well, respectively, after the step (j) thereby
forming a first p-channel MISFET having source and drain comprising the p-semiconductor region, the first gate insulative film, a gate electrode including the p-semiconductor piece and the second nitridation region in the first n-well,
forming a second p-channel MISFET having source and drain comprising the p-semiconductor region, the second insulative film, a gate electrode including the p-semiconductor piece and the first nitridation region in the second n-well,
forming a first n-channel MISFET having source and drain comprising the n-semiconductor region, the first insulative film, a gate electrode including the n-semiconductor piece and the fourth nitridation region in the first p-well, and
forming a second n-channel MISFET having source and drain comprising the n-semiconductor region, the second insulative film, a gate electrode containing the n-semiconductor piece and the fifth nitridation region in the second n-well,.

10. A method of manufacturing a semiconductor integrated circuit device comprising the following steps of;
(a) forming a first agate insulative film in a first region on a main surface of a semiconductor substrate and forming a second gate insulative film having a thickness larger than the first gate insulative film in the second region on the main surface of the semiconductor substrate,
(b) applying a heat treatment to the semiconductor substrate in an atmosphere containing nitrogen, thereby forming a first nitridation region having a first nitrogen concentration to the boundary between the semiconductor substrate and the second insulative film in the second region, and forming a second nitridation region having a second nitrogen concentration higher than the first nitrogen concentration to the boundary between the semiconductor substrate and the first gate insulative film in the first region,
(c) forming a conductor film above the first and the second gate insulative films after the step (b), and ion implanting n-impurities through the conductor film to the semiconductor substrate in the first and the second regions for controlling the threshold voltage of a n-channel MISFET,
(d) forming a photoresist film on the conductor film in the first region and ion implanting n-impurities through the conductor film in the second region to the semiconductor substrate in the second region, thereby optimizing the threshold voltage of the n-channel MISFET formed to the semiconductor substrate in the second region,
(e) ion implanting nitrogen through the conductor film in the second region to the semiconductor substrate in the second region while leaving the photoresist film on the conductor film in the first region, thereby forming a third nitridation region containing nitrogen in the first nitridation region as a portion thereof and having a third nitrogen concentration equal with or higher than the second nitrogen concentration to the boundary between the semiconductor substrate in the second region and the second gate insulative film,
(f) forming a semiconductor piece above each of the first and the second gate insulative films by patterning the conductor film,
(g) forming source and drain comprising an n-semiconductor region to the semiconductor substrate in the first and the second regions, respectively, after the step (f) thereby forming a first n-channel MISFET having source and drain comprising the n-semiconductor region, the first gate insulative film, a gate electrode including the semiconductor piece and the second nitridation region to the semiconductor substrate in the first region and,
forming a second n-channel MISFET having source and drain comprising the n-semiconductor region, the second gate insulative film a gate electrode including the semiconductor piece and the third nitridation region to the semiconductor substrate in the second region.

11. A method of manufacturing a semiconductor integrated circuit device comprising the following steps of:
(a) forming p-well and n-well on a main surface of a semiconductor substrate and then forming a gate insulative film to the surface for each of the p-well and the n-well,
(b) applying a heat treatment to the semiconductor substrate in an atmosphere containing nitrogen thereby forming a first nitridation region having a first nitrogen concentration to the boundary between the p-well and the gate insulative film and to the boundary between the n-well and the gate insulative film
(c) forming a silicon film on the gate insulative film after the step (b),
(d) covering the silicon film above the n-well with a first photoresist film, and ion implanting n-impurities in the silicon film above the p-well, thereby forming an n-silicon film,
(e) ion implanting nitrogen through the n-silicon film to the p-well while leaving the first photoresist film on the silicon film, thereby forming a second nitridation region containing nitrogen in the first nitridation region as a portion thereof and having a second nitrogen concentration higher than the first nitrogen concentration to the boundary between the p-well and the gate insulative film,
(f) covering the n-silicon film with a second photoresist film and ion implanting p-impurities in the silicon film above the n-well thereby forming a p-silicon film,
(g) patterning each of the n-silicon film and the p-silicon film, thereby forming an n-semiconductor piece comprising the n-silicon film above the p-well and forming a p-semiconductor piece comprising the p-silicon film above the n-well, and
(h) forming source and drain comprising an n-semiconductor region in the p-well and forming source and drain comprising a p-semiconductor region in the n-well after the step (g) thereby
forming a p-channel MISFET having source and drain comprising the p-semiconductor region, the gate insulative film, a gate electrode including the p-semiconductor piece and the first nitridation film, in the n-well, and
forming an n-channel MISFET having source and drain comprising the n-semiconductor region, the gate insulative film, a gate electrode including the n-semiconductor piece and the second nitridation region, in the p-well.
